(19) United States
(12) Patent Application Publication
(10) Pub. No.: US 2026/0353794 A1
(43) Pub. Date: Nov. 5, 2026

(54) SEMICONDUCTOR DEVICE WITH COMPLEMENTARY FIELD-EFFECT TRANSISTORS AND NANOSTRUCTURE FIELD-EFFECT TRANSISTORS AND METHODS OF FORMING

(71) Applicant: Taiwan Semiconductor Manufacturing Co., Ltd., Hsinchu (TW)

(72) Inventors: Cheng-Ting Chung, Hsinchu City (TW); Hou-Yu Chen, Zhubei City (TW)

(21) Appl. No.: 19/741,334

(22) Filed: Jul. 14, 2026

Related U.S. Application Data
(63) Continuation of application No. 19/029,820, filed on Jan. 17, 2025.
(60) Provisional application No. 63/699,629, filed on Sep. 26, 2024.

(51) Int. Cl. H10D 84/85; H10D 84/01

(52) U.S. Cl. CPC H10D 84/856; H10D 84/0167; H10D 84/017; H10D 84/0188; H10D 84/851

(57) ABSTRACT

Both complementary field-effect transistors (CFETs) and nanostructure field-effect transistors (NSFETs) are formed over a same substrate to form a semiconductor device. The CFETs achieve high transistor integration density by vertically stacking transistors together and may be suitable for implementing advanced logic circuits. The NSFETs achieve high driving current and may be suitable for high-performance cells and/or special cells such as unipolar cells. The structures and process flows disclosed herein allow for the coexistence of CFETs and NSFETs in the same semiconductor die to take advantage of the benefits of both CFETs and NSFETs. The disclosed process flow can be easily integrated into current process flow for forming NSFET devices, and helps to advance the development of CFET technology and enable the creation of more efficient and powerful semiconductor devices.

### PRIORITY CLAIM AND CROSS-REFERENCE

This application is a continuation of U.S. patent application Ser. No. 19/029,820, filed Jan. 17, 2025 and entitled “Semiconductor Device with Complementary Field Effect Transistors and Nanostructure Field Effects Transistors and Methods of Forming,” which application claims priority to U.S. Provisional Application No. 63/699,629, filed Sep. 26, 2024 and entitled “Coexistence of Stacking Transistor and Conventional Nanosheet,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provide a promising new architecture that achieves improved integration density by forming nanostructure field-effect transistors (FET) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a complementary field-effect transistor (CFET) in a three-dimensional view, in accordance with an embodiment.

FIG. 2 illustrates a nanostructure field-effect transistor (NSFET) device in a three-dimensional view, in accordance with an embodiment.

FIGS. 3, 4A, 4B, 5A, 5B, 6A, 6B, 7A-7D, 8A-8D, 9A-9D, 10A-10D, 11A, 11B, 12A-12D, 13A, 13B, 14A, and 14B are cross-sectional views of a semiconductor device at various stages of manufacturing, in accordance with an embodiment.

FIG. 15 a cross-sectional view of a semiconductor device, in accordance with another embodiment.

FIGS. 16A and 16B together illustrate a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion, unless otherwise specified, the same or similar reference numerals in different figures refer to the same or similar element formed by a same or similar material(s) using the same or similar formation method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, both CFETs and NSFETs are formed over a same substrate to form a semiconductor device. The CFETs achieve high transistor integration density by vertically stacking transistors together and may be suitable for implementing advanced logic circuits. The NSFETs achieve high driving current and may be suitable for high-performance cells and/or special cells such as unipolar cells. The structures and process flows disclosed herein allow for the coexistence of CFETs and NSFETs in the same semiconductor die to take advantage of the benefits of both CFETs and NSFETs. The disclosed embodiments help to advance the development of CFET technology and enable the creation of more efficient and powerful semiconductor devices. In addition, the disclosed process flow can be easily integrated into current process flow for forming NSFET devices.

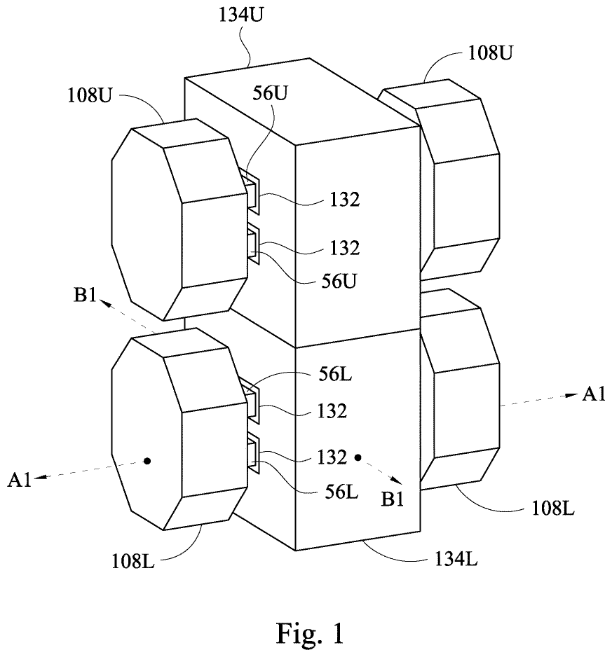

FIG. 1 illustrates an example of a CFET 10, in accordance with an embodiment. FIG. 1 is a three-dimensional view, where some features of the CFET 10 are omitted for illustration clarity. The CFET 10 may be a part of a semiconductor device that includes multiple CFETs.

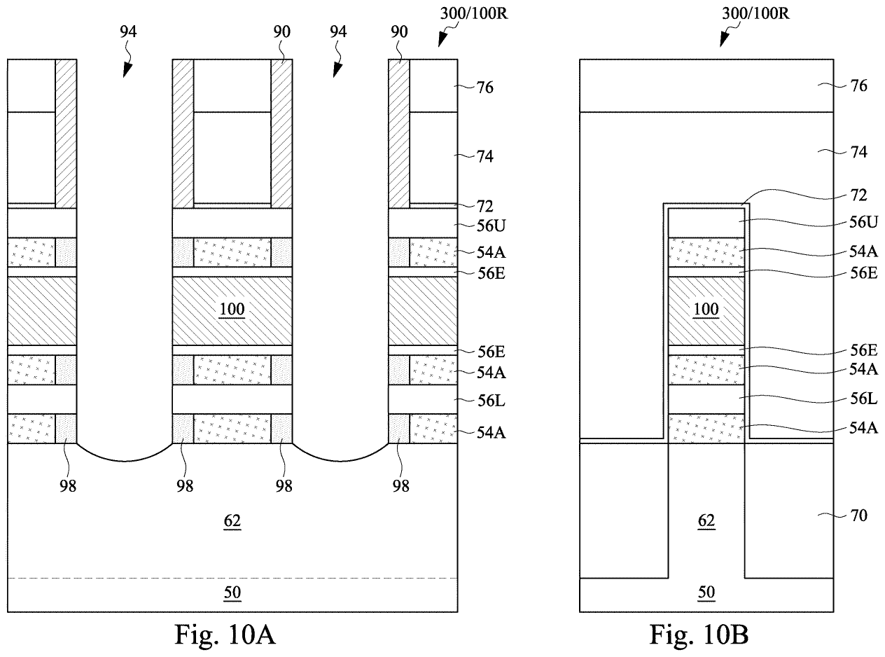

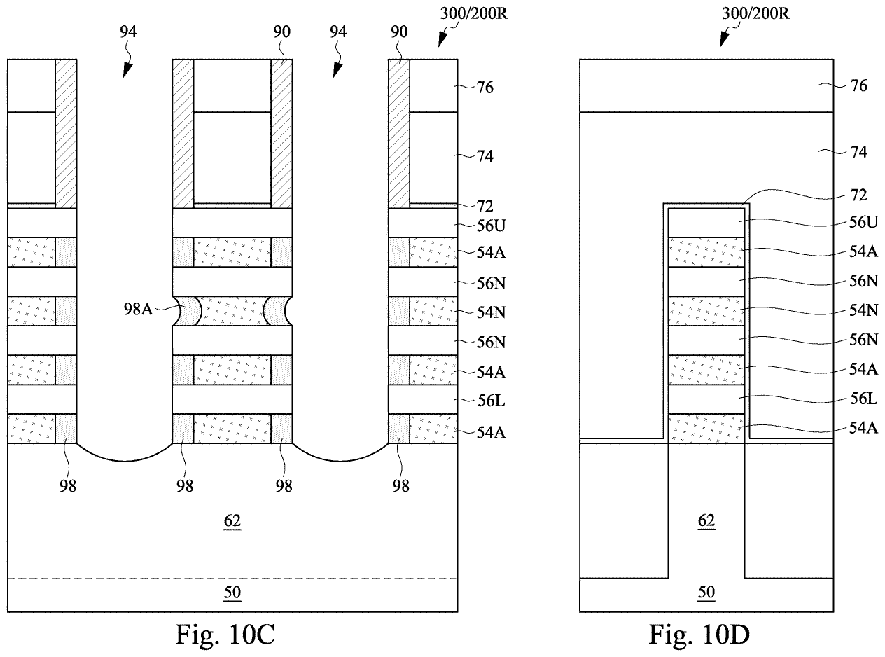

The CFET 10 includes vertically stacked nanostructure FETs (e.g., nanowire FETs, nanosheet FETs, multi bridge channel (MBC) FETs, nanoribbon FETs, gate-all-around (GAA) FETs, or the like). For example, the CFET 10 may include a lower nanostructure FET of a first device type (e.g., n-type/p-type) and an upper nanostructure FET of a second device type (e.g., p-type/n-type) that is opposite the first device type. Specifically, the CFET 10 may include a lower PMOS transistor and an upper NMOS transistor, or the CFET 10 may include a lower NMOS transistor and an upper PMOS transistor. Note that the structure of CFET 10 also allows nanostructure FETs (NSFETs) of the same device type to be vertically stacked to form semiconductor devices. Therefore, the terminology CFET is used herein as a generic term to refer to the vertically stacked nature of the device structure, and is not limited to vertically stacked transistors of opposite device types. Each of the nanostructure FETs include semiconductor nanostructures 56 (e.g., lower semiconductor nanostructures 56L, or upper semiconductor nanostructures 56U), where the semiconductor nanostructures 56 act as channel regions (also referred to as channel layers, semiconductor channels regions, or semiconductor channel layers) for the nanostructure FETs. The semiconductor nanostructures 56 may be nanosheets, nanowires, or the like. The lower semiconductor nanostructures 56L (may also be referred to as lower nanostructures 56L) are for a lower nanostructure FET and the upper semiconductor nanostructures 56U (may also be referred to as upper nanostructures 56U) are for an upper nanostructure FET. Isolation structures (not explicitly illustrated in FIG. 1, see, e.g., 100 in FIGS. 10A and 10B) may be used to separate and electrically isolate the upper semiconductor nanostructures 56U from the lower semiconductor nanostructures 56L. For simplicity, a semiconductor nanostructure may also be referred to as a nanostructure hereinafter.

In FIG. 1, gate dielectric layers 132 are along top surfaces, sidewalls, and bottom surfaces of the semiconductor nanostructures 56. Gate electrodes 134 (including a lower gate electrode 134L and an upper gate electrode 134U) are over the gate dielectric layers 132 and around the semiconductor nanostructures 56. Source/drain regions 108 (including lower epitaxial source/drain regions 108L and upper epitaxial source/drain regions 108U) are disposed at opposing sides of the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, the lower gate electrode 134L may optionally be separated from the upper gate electrode 134U by an isolation layer. Alternatively, a lower gate electrode 134L may be coupled to (e.g., directly connected to) an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, CFETs may also be referred to as stacking transistors or folding transistors.

FIG. 1 further illustrates reference cross-sections that are used in later figures. Cross-section A1-A1 is parallel to a longitudinal axis of the semiconductor nanostructures 56 of a CFET and in a direction of, for example, a current flow between the source/drain regions 108 of the CFET. Cross-section B1-B1 is perpendicular to cross-section A1-A1 and along a longitudinal axis of a gate electrode 134 of a CFET. Subsequent figures refer to these reference cross-sections for clarity.

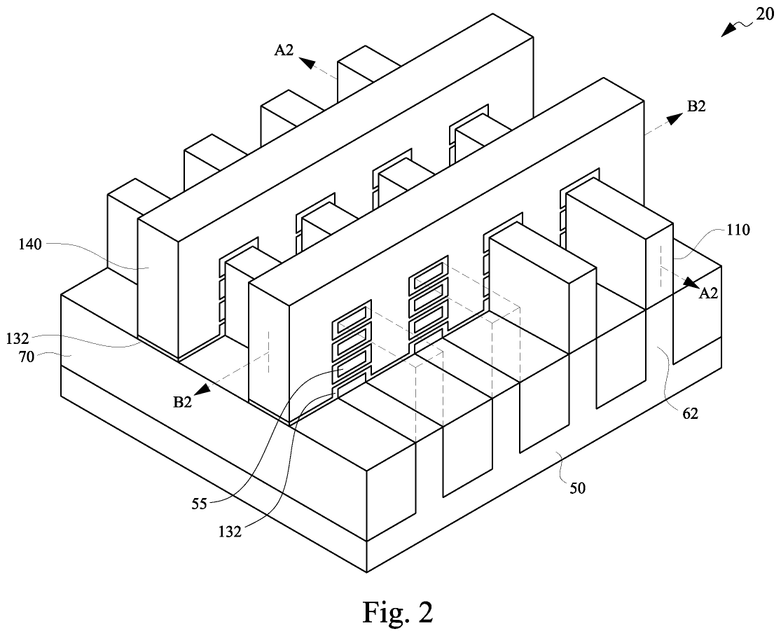

FIG. 2 illustrates a nanostructure field-effect transistor (NSFET) device 20 in a three-dimensional view, in accordance with an embodiment. Note that some features of the NSFET device 20 are omitted for illustration clarity. The NSFET device 20 includes multiple NSFETs.

The NSFET device 20 comprises semiconductor fins 62 (also referred to as fins) protruding above a substrate 50. Gate electrodes 140 (e.g., metal gates) are disposed over the fins, and source/drain regions 110 are formed on opposing sides of the gate electrodes 140. A plurality of nanostructures 56 (e.g., nanowires, or nanosheets) are formed over the fins 62 and between source/drain regions 110. Isolation regions 70 are formed on opposing sides of the fins 62. Gate dielectric layers 132 are formed around the nanostructures 56. Gate electrodes 140 are over and around the gate dielectric layers 132.

FIG. 2 further illustrates reference cross-sections that are used in later figures. Cross-section B2-B2 is along a longitudinal axis of the gate electrode 140 and in a direction, for example, perpendicular to the direction of current flow between the source/drain regions 110 of the NSFET device 20. Cross-section A2-A2 is perpendicular to cross-section B2-B2 and is along a longitudinal axis of the fin 62 and in a direction of, for example, a current flow between the source/drain regions 110 of the NSFET device 20. Subsequent figures may refer to these reference cross-sections for clarity.

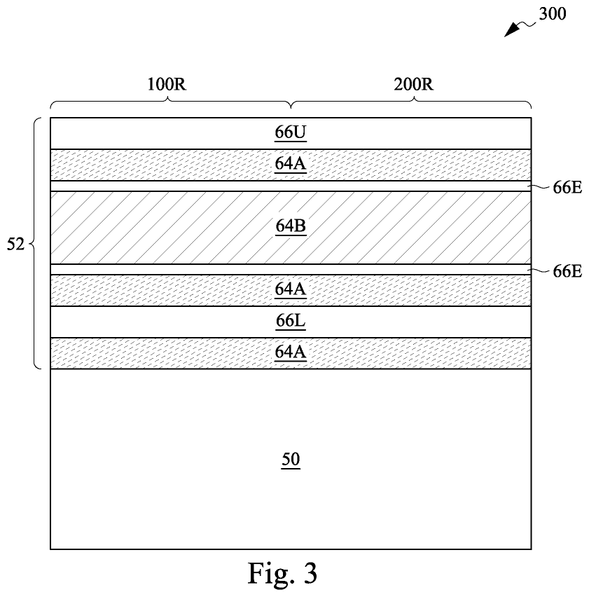

FIGS. 3, 4A, 4B, 5A, 5B, 6A, 6B, 7A-7D, 8A-8D, 9A-9D, 10A-10D, 11A, 11B, 12A-12D, 13A, 13B, 14A, and 14B are cross-sectional views of a semiconductor device 300 at various stages of manufacturing, in accordance with an embodiment. Note for illustration clarify, not all features of the semiconductor device 300 are illustrated. In the illustrated embodiments, the semiconductor device 300 includes a first device region 100R for forming CFETs, and includes a second device region 200R for forming NSFETs. In other words, the semiconductor device 300 integrates both CFETs and NSFETs on a same substrate 50.

FIG. 3 illustrates a first device region 100R and a second device region 200R of the substrate 50. In the illustrated embodiments, CFETs are formed in the first device region 100R, and NSFETs are formed in the second device region 200R. Therefore, the first device region 100R and the second device region 200R may also be referred to as the CFET region 100R of the semiconductor device 300 and the NSFET region 200R of the semiconductor device 300, respectively. The first device region 100R and the second device region 200R may be immediately adjacent to each other, or may be spaced apart from each other.

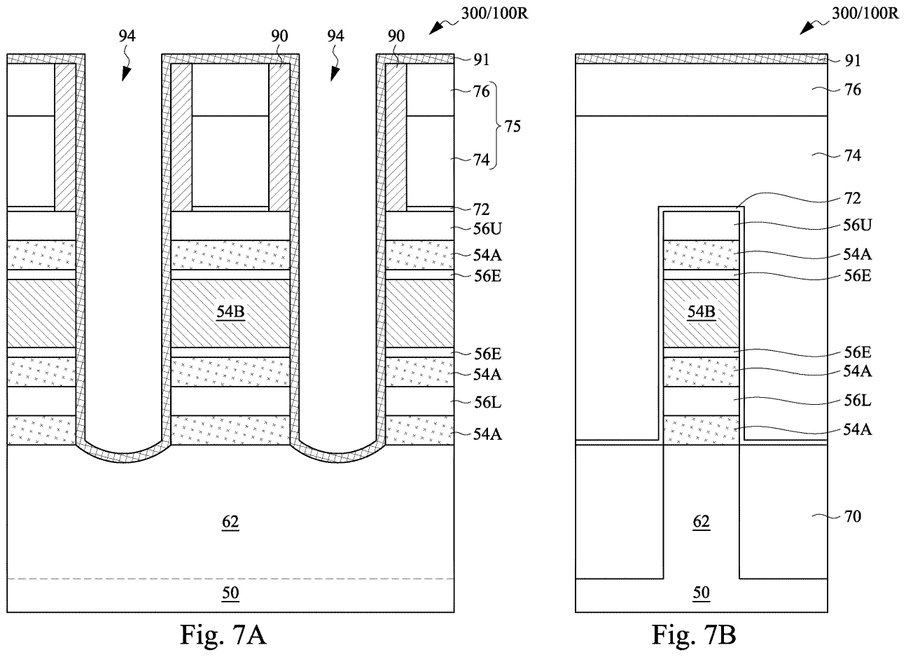

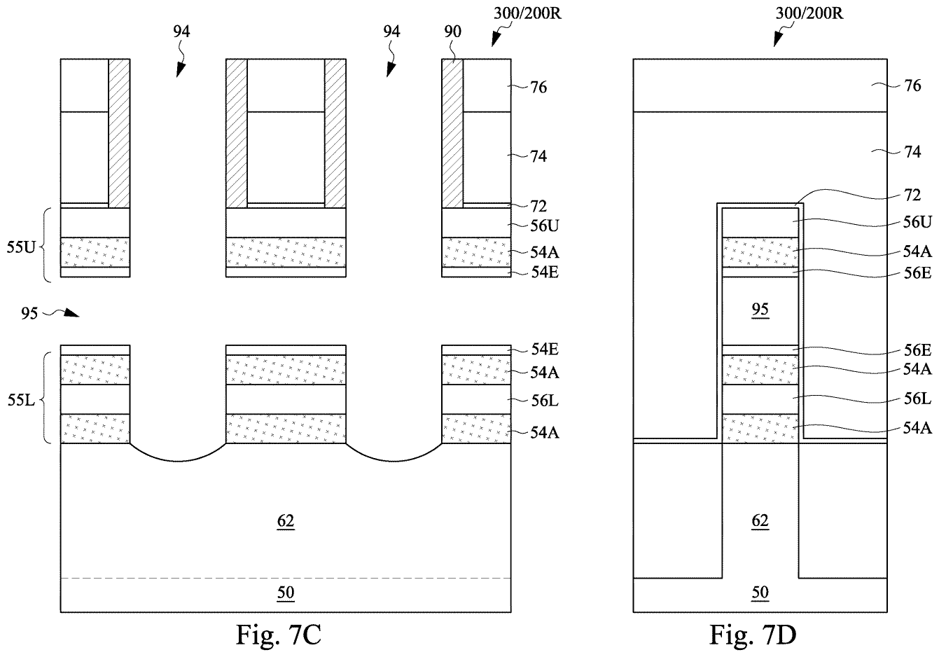

The processing steps illustrated in FIGS. 3, 4A, 4B, 5A, 5B, 6A, and 6B are the same for both the CFET region 100R and the NSFET region 200R. In other words, the illustrated processing steps are performed for both the CFET region 100R and the NSFET region 200R. Subsequent processing steps for the CFET region 100R and the NSFET region 200R are different. For example, FIGS. 7A, 7B, 8A, 8B, 9A, 9B, 10A, 10B, 11A, 12A, 12B, 13A, and 14A illustrate processing steps for the CFET region 100R, whereas FIGS. 7C, 7D, 8C, 8D, 9C, 9D, 10C, 10D, 11B, 12C, 12D, 13B, and 14B illustrate processing steps for the NSFET region 200R.

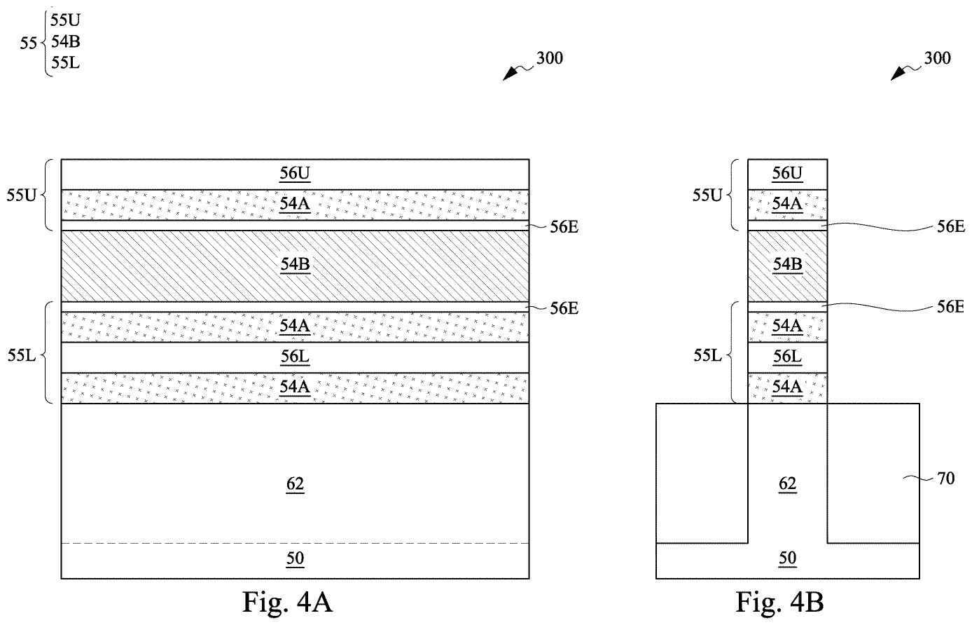

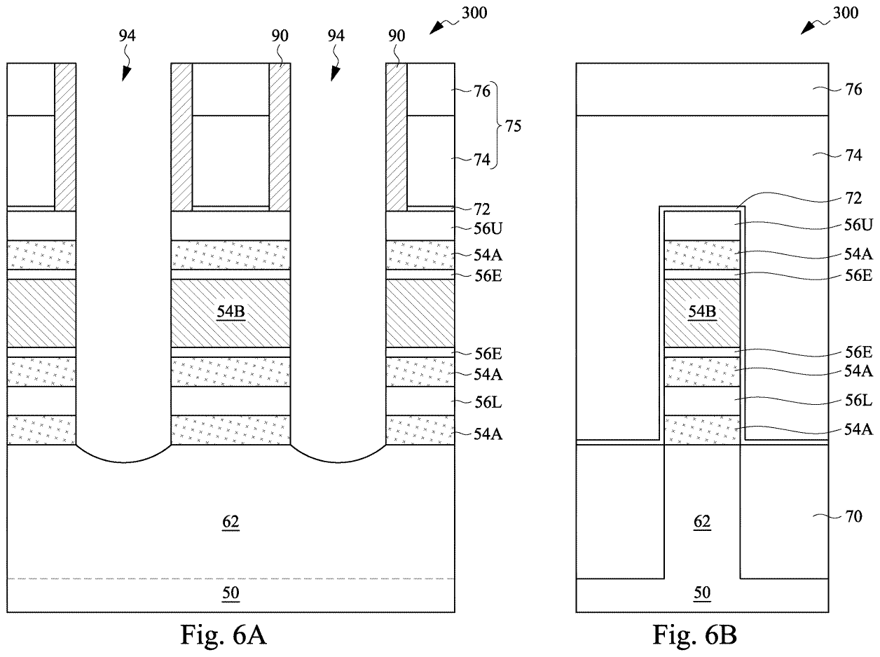

FIGS. 3, 4A, 5A, and 6A illustrate cross-sectional views along cross-section A1-A1 of FIG. 1, or cross-section A2-A2 of FIG. 2. FIGS. 4B, 5B, and 6B illustrate cross-sectional views along cross-section B1-B1 of FIG. 1, or cross-section B2-B2 of FIG. 2. FIGS. 7A, 8A, 9A, 10A, 11A, 12A, 13A, and 14A illustrate cross-sectional views along cross-section A1-A1 of FIG. 1. FIGS. 7B, 8B, 9B, 10B, and 12B illustrate cross-sectional views along cross-section B1-B1 of FIG. 1. FIGS. 7C, 8C, 9C, 10C, 11B, 12C, 13B, and 14B illustrate cross-sectional views along cross-section A2-A2 of FIG. 2. FIGS. 7D, 8D, 9D, 10D, and 12D illustrate cross-sectional views along cross-section B2-B2 of FIG. 2. Throughout the discussion herein, figures with the same numeral but different alphabets (e.g., FIGS. 6A and 6B) illustrate different views (e.g., along different cross-sections) of the same semiconductor device at the same stage of processing.

In FIG. 3, a substrate 50 is provided, and a multi-layer stack 52 is formed over the substrate 50. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The multi-layer stack 52 is formed over the substrate 50. The multi-layer stack 52 includes dummy layers 64 (including first dummy layers 64A and a second dummy layer 64B) and semiconductor layers 66 (including lower semiconductor layers 66L and upper semiconductor layers 66U). The lower semiconductor layers 66L and a subset of the first dummy layers 64A are disposed below the second dummy layer 64B, and are interleaved with each other (e.g., forming an alternating layer pattern). The upper semiconductor layers 66U and another subset of the first dummy layers 64A are disposed above the second dummy layer 64B, and are interleaved with each other.

In the example of FIG. 3, the multi-layer stack 52 further includes etch stop layers (ESLs) 66E formed above and below the second dummy layer 64B. In other words, the second dummy layer 64B is sandwiched between the etch stop layers 66E. In some embodiments, the etch stop layers 66E are formed of a same material as the semiconductor layers 66 using the same or similar formation method. In the illustrated embodiments, the etch stop layers 66E are formed to be thinner than the dummy layers 64 and the semiconductor layers 66. For example, the etch stop layers 66E may have a thickness that is 30%, 20%, 10%, or less, of the thickness of the dummy layers 64 (or the semiconductor layers 66).

As subsequently described in greater detail, the dummy layers 64 will be removed and the semiconductor layers 66 will be patterned to form channel regions of CFETs and NFETs. For example, in the CFET region 100R, the lower semiconductor layers 66L will be patterned to form channel regions of the lower nanostructure FETs of the CFETs, and the upper semiconductor layers 66U will be patterned to form channel regions of the upper nanostructure FETs of the CFETs.

The number of the dummy layers 64 and the number of the semiconductor layers 66 illustrated in FIG. 3 are merely non-limiting examples. It should be appreciated that the multi-layer stack 52 may include any number of the dummy layers 64 and the semiconductor layers 66. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 64A are formed of a first semiconductor material, and the second dummy layer 64B is formed of a second semiconductor material. The first and second semiconductor materials may be selected from the candidate semiconductor materials of the substrate 50. The semiconductor materials of the first dummy layers 64A and the second dummy layer 64B will be subsequently described in greater detail. The first and second semiconductor materials have a high etching selectivity to one another. As such, the material of the second dummy layer 64B may be removed at a faster rate than the material of the first dummy layers 64A in subsequent processing.

The semiconductor layers 66 (including the lower semiconductor layers 66L and upper semiconductor layers 66U) are formed of one or more semiconductor material(s). The semiconductor material(s) may be selected from the candidate semiconductor materials of the substrate 50. In some embodiments, the semiconductor layers 66 are formed of a group IV-V material or a group III-V material. The lower semiconductor layers 66L and the upper semiconductor layers 66U may be formed of the same semiconductor material, or may be formed of different semiconductor materials. In some embodiments, the lower semiconductor layers 66L and the upper semiconductor layers 66U are both formed of a semiconductor material suitable for p-type devices and n-type devices, such as silicon. In some embodiments, the lower semiconductor layers 66L are formed of a semiconductor material suitable for p-type devices, such as germanium or silicon-germanium, and the upper semiconductor layers 66U are formed of a semiconductor material suitable for n-type devices, such as silicon or carbon-doped silicon. The semiconductor material(s) of the semiconductor layers 66 will be subsequently described in greater detail. The semiconductor material(s) of the semiconductor layers 66 have a high etching selectivity to the semiconductor materials of the dummy layers 64. As such, the materials of the dummy layers 64 may be removed at a faster rate than the material of the semiconductor layers 66 in subsequent processing.

Some layers of the multi-layer stack 52 may be thicker than other layers of the multi-layer stack 52. The thickness of the second dummy layer 64B may be different (e.g., greater or less) than the thickness of each of the first dummy layers 64A. In some embodiments, the second dummy layer 64B has a large thickness, such as a greater thickness than each of the first dummy layers 64A. Forming the second dummy layer 64B to a large thickness allows the second dummy layer 64B to be more easily removed in subsequent processing. Additionally, the thickness of each of the semiconductor layers 66 may be different (e.g., greater or less) than the thickness(es) of each of the first dummy layers 64A and/or the second dummy layer 64B. In some embodiments, each of the semiconductor layers 66 may be thicker than each of the dummy layers 64.

In some embodiments, the first dummy layers 64A are formed of silicon-germanium with a first germanium atomic percentage, the second dummy layer 64B is formed of silicon-germanium with a second germanium atomic percentage that is higher than the first germanium atomic percentage. The difference between the second germanium atomic percentage and the first germanium atomic percentage may be higher than, e.g., about 10 percent or 30 percent, and may be in the range between about 30 percent and about 70 percent. The higher germanium atomic percentage allows the second dummy layer 64B to be etched at a faster rate than the first dummy layers 64A, and allows the second dummy layer 64B to be completed removed during a subsequent etching process, as discussed hereinafter.

Next, in FIGS. 4A and 4B, fins 62 are formed in the substrate 50 and nanostructures 54, 56 (including first dummy nanostructures 54A, second dummy nanostructures 54B, lower semiconductor nanostructures 56L, and upper semiconductor nanostructures 56U) are formed in the multi-layer stack 52. The number of fins 62 illustrated is illustrative and non-limiting. In some embodiments, the nanostructures 54, 56 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 54, 56 by etching the multi-layer stack 52 may define the first dummy nanostructures 54A from the first dummy layers 64A, the second dummy nanostructures 54B from the second dummy layer 64B, the lower semiconductor nanostructures 56L from the lower semiconductor layers 66L, and the upper semiconductor nanostructures 56U from the upper semiconductor layers 66U. The ESLs 66E of the multi-layer stack 52 are patterned to form nanostructures 56E (may also be referred to as ESLs 56E) by the anisotropic etching, in some embodiments.

The first dummy nanostructures 54A and the second dummy nanostructures 54B may be collectively referred to as the dummy nanostructures 54. The lower semiconductor nanostructures 56L and the upper semiconductor nanostructures 56U may further be collectively referred to as the semiconductor nanostructures 56. The nanostructures (e.g., 54A, 56L, and 56E) below the second dummy nanostructures 54B may be collectively referred to as lower nanostructures 55L, and the nanostructures (e.g., 54A, 56U, and 56E) above the second dummy nanostructures 54B may be collectively referred to as upper nanostructures 55U. The lower nanostructures 55L, the second dummy nanostructures 54B, and the upper nanostructures 55U may be collectively referred to as nanostructures 55. In the example of FIGS. 4A and 4B, each of the second dummy nanostructures 54B is interposed between a lower nanostructure 55L and an upper nanostructure 55U.

As subsequently described in greater detail, the dummy nanostructures 54 in the CFET region 100R will be removed to form channel regions of CFETs. Specifically, the lower nanostructures 56L will act as channel regions for lower nanostructure FETs of the CFETs. Additionally, the upper nanostructures 56U will act as channel regions for upper nanostructure FETs of the CFETs. The second dummy nanostructures 54B will be subsequently replaced with isolation structures. The isolation structures may define boundaries of the lower nanostructure FETs and the upper nanostructure FETs of the CFETs.

The fins 62 and the nanostructures 54, 56 may be patterned by any suitable method. For example, the fins 62 and the nanostructures 54, 56 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 54, 56. In some embodiments, a mask (or other layer) may remain on the nanostructures 54, 56.

In FIG. 4, isolation regions 70 are formed adjacent to the fins 62. The isolation regions 70 may be formed by depositing an insulating material over the substrate 50, the fins 62, and nanostructures 54, 56, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 54, 56. Although the insulating material is illustrated as a single layer, some embodiments may utilize multiple layers. For example, in some embodiments a liner (not separately illustrated) may first be formed along a surface of the substrate 50, the fins 62, and the nanostructures 54, 56. Thereafter, a fill material, such as one of the previously described insulating materials may be formed over the liner.

A removal process is then applied to the insulating material to remove excess insulating material over the nanostructures 54, 56. In some embodiments, a planarization process such as a chemical mechanical polish (CMP), an etch-back process, combinations thereof, or the like may be utilized. The planarization process exposes the nanostructures 54, 56 such that top surfaces of the nanostructures 54, 56 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 54, 56). For example, an etching process using dilute hydrofluoric (dHF) acid may be performed to recess the isolation regions 70.

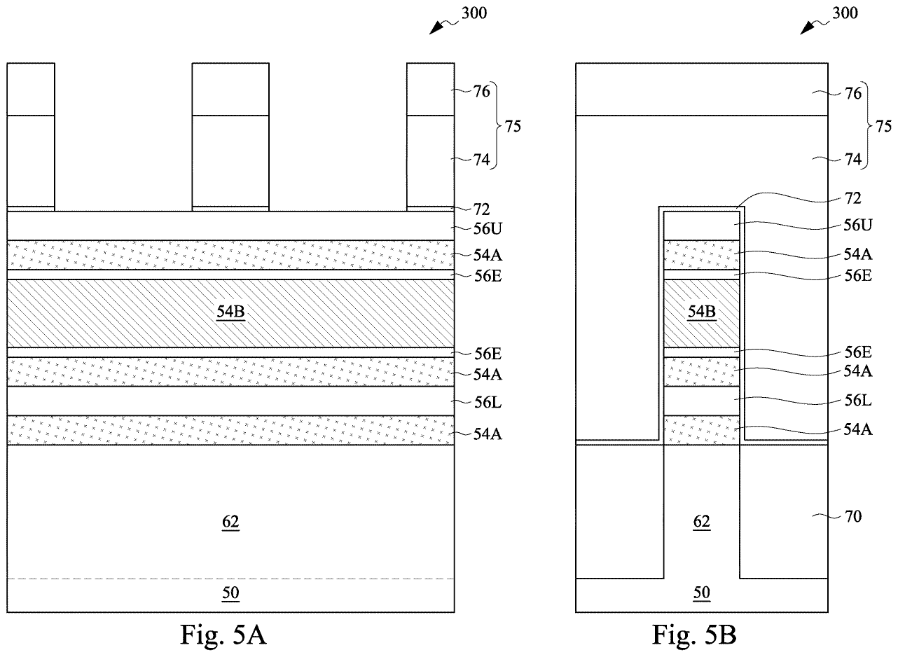

Next, in FIGS. 5A and 5B, a dummy dielectric layer 72 is formed on the fins 62 and/or the nanostructures 54, 56. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 54, 56.

Next, the mask layer 76 is patterned using acceptable photolithography and etching techniques to form masks 76. The pattern of the masks 76 is then transferred to the dummy gate layer 74 and to the dummy dielectric layer 72 to form dummy gates 74 and dummy dielectrics 72, respectively. The dummy gates 74 and the dummy dielectrics 72 are collectively referred to as dummy gate structures 75. The dummy gates 74 cover respective channel regions of the nanostructures 56. The pattern of the masks 76 may be used to physically separate each of the dummy gates 74 from adjacent dummy gates 74. The dummy gates 74 may also have a lengthwise direction substantially perpendicular to the lengthwise direction of respective fins 62. The masks 76 can optionally be removed after patterning, such as by any acceptable etching technique.

Next, in FIGS. 6A and 6B, gate spacers 90 are formed over the nanostructures 54, 56 and on exposed sidewalls of the masks 76 (if present), the dummy gates 74, and the dummy dielectrics 72. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as CVD, ALD, or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gate structures 75 (thus forming the gate spacers 90). Fin spacers may also be formed as part of forming the gate spacers 90.

Next, source/drain recesses 94 (also referred to as source/drain openings) are formed in the nanostructures 54, 56, and the fins 62. Epitaxial source/drain regions will be subsequently formed in the source/drain recesses 94. The source/drain recesses 94 may extend through the nanostructures 54, 56 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 54, 56, and the fins 62 using anisotropic etching processes, such as RIE, NBE, or the like. The gate spacers 90 and the dummy gate structures 75 mask portions of the nanostructures 54, 56, and the fins 62 during the etching processes used to form the source/drain recesses 94. A single etch process or multiple etch processes may be used to etch each layer of the nanostructures 54, 56, and the fins 62. Timed etch processes may be used to stop the etching of the source/drain recesses 94 after the source/drain recesses 94 reach a desired depth.

Next, as illustrated by FIGS. 7A-7D, a mask 91 is formed to cover the CFET region 100R while exposing the NSFET region 200R. Note that in FIGS. 7A-7D (and subsequent figures), the notation 300/100R in a figure is used to indicate that the figure shows (a portion of) the CFET region 100R of the semiconductor device 300, and the notation 300/200R in a figure is used to indicate that the figure shows (a portion of) the NSFET region 200R of the semiconductor device 300.

The mask 91 may be formed by conformally depositing a mask layer (e.g., silicon nitride, silicon oxynitride, or the like) over the CFET region 100R and the NSFET region 200R, then patterning the deposited mask layer to remove the mask layer from the NSFET region 200R. As illustrated in FIG. 7A, the mask 91 lines sidewalls and bottoms of the source/drain recesses 94 in the CFET region 100R. In contrast, sidewalls and bottoms of the source/drain recesses 94 in the NSFET region 200R are exposed.

Next, as illustrated in FIGS. 7C and 7D, the second dummy nanostructures 54B in the NSFET region 200R are removed. In some embodiments, a selectively etching process is performed using an etchant selective to (e.g., having a higher etching rate for) the material of the second dummy nanostructures 54B, such that the second dummy nanostructures 54B are completely removed without substantially attacking other materials of the semiconductor device 300. The selective etching process is an isotropic etching process, in an example embodiment. In some embodiments where the second dummy nanostructures 54B are formed of germanium or silicon germanium with a high germanium atomic percentage, the first dummy nanostructures 54A are formed of silicon germanium with a low germanium atomic percentage, and the semiconductor nanostructures 56 are formed of silicon, the selective etching process may comprise a dry etch process using chlorine gas, with or without a plasma. Because the dummy gate structures 75 warp around sidewalls of the nanostructures 56 and 54 (see FIG. 7D), the dummy gate structures 75 may support the upper nanostructures 55U so that the upper nanostructures 55U do not collapse upon removal of the second dummy nanostructures 54B. After the removal of the second dummy nanostructures 54B, gaps 95 (e.g., empty spaces) are formed between the upper nanostructures 55U and lower nanostructures 55L. As illustrated in FIGS. 7C and 7D, the gaps 95 expose the lower surfaces of the nanostructures 56E of the upper nanostructures 55U, and expose the upper surfaces of the nanostructures 56E of the lower nanostructures 55L.

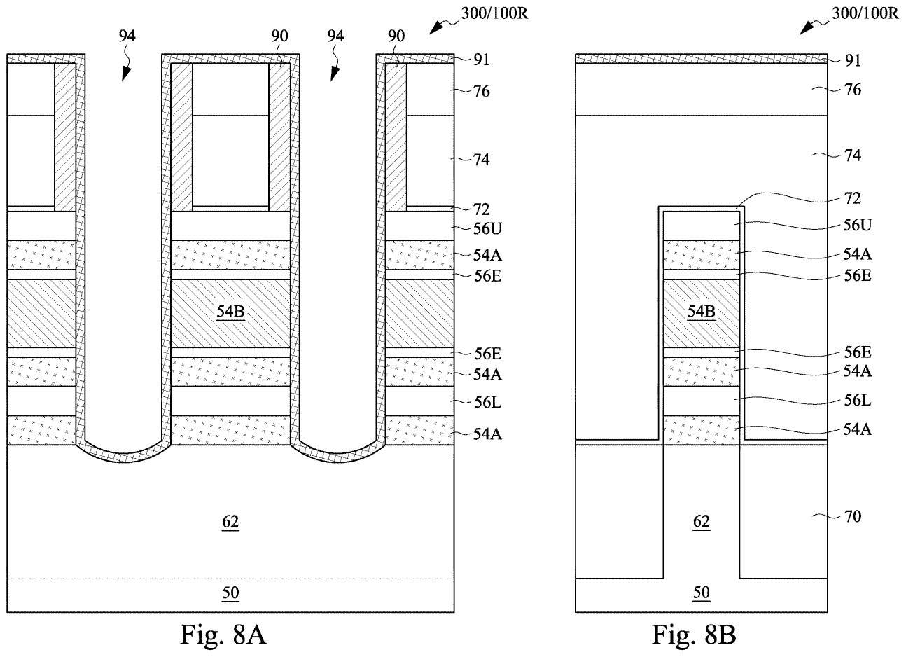

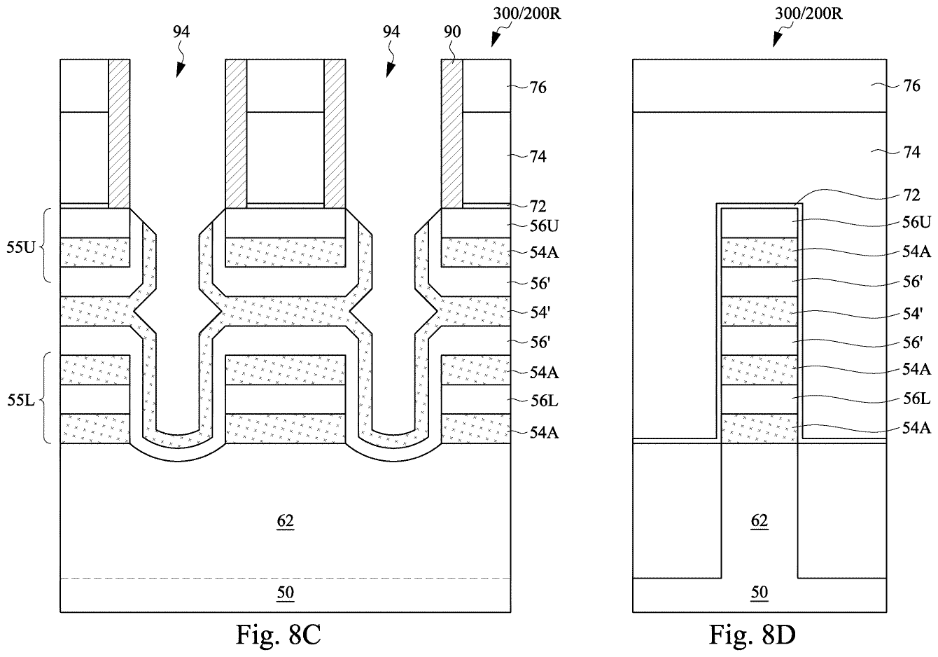

Next, in FIGS. 8A-8D, a semiconductor material 56′ (e.g., silicon), which is the same as the semiconductor material of the nanostructures 56E (and/or 56U, 56L), is formed (e.g., conformally) along exposed surfaces of the upper nanostructures 55U and along exposed surfaces of the lower nanostructures 55L. The semiconductor material 56′ may merge with the nanostructures 56E, and there may or may not be interfaces between the semiconductor material 56′ and the nanostructures 56E. In the example of FIG. 8C, the numeral 56′ is used to annotate the merged semiconductor material 56′ and the nanostructures 56E. The semiconductor material 56′ may be formed by a suitable formation method, such as PVD, CVD, ALD, or the like. In some embodiments, an epitaxial growth process is performed to form the semiconductor material 56′ selectively on exposed surfaces of the upper nanostructures 55U and exposed surfaces of the lower nanostructures 55L, such that little or no semiconductor material 56′ is formed along surfaces of the gate spacers 90 and the mask 76. As shown in FIG. 8C, the semiconductor material 56′ is formed along the lower surfaces of the nanostructures 56E of the upper nanostructures 55U, and along the upper surfaces of the nanostructures 56E of the lower nanostructures 55L. Notably, the semiconductor material 56′ only partially fills the gaps 95.

Next, a semiconductor material 54′ (e.g., silicon germanium), which is the same as the semiconductor material of the first dummy nanostructures 54A, is formed (e.g., conformally) along exterior surfaces of the semiconductor material 56′. The semiconductor material 54′ fills (e.g., completely fills) the remaining portions of the gaps 95, in some embodiments. The semiconductor material 54′ may be formed by a suitable formation method, such as PVD, CVD, ALD, or the like. In some embodiments, an epitaxial growth process may be performed to selectively form the semiconductor material 54′ on the exterior surfaces of the semiconductor material 56′. Note that due to the mask 91 covering the CFET region 100R, the semiconductor materials 56′ and 54′ are not formed in the CFET region 100R, in the illustrated embodiments.

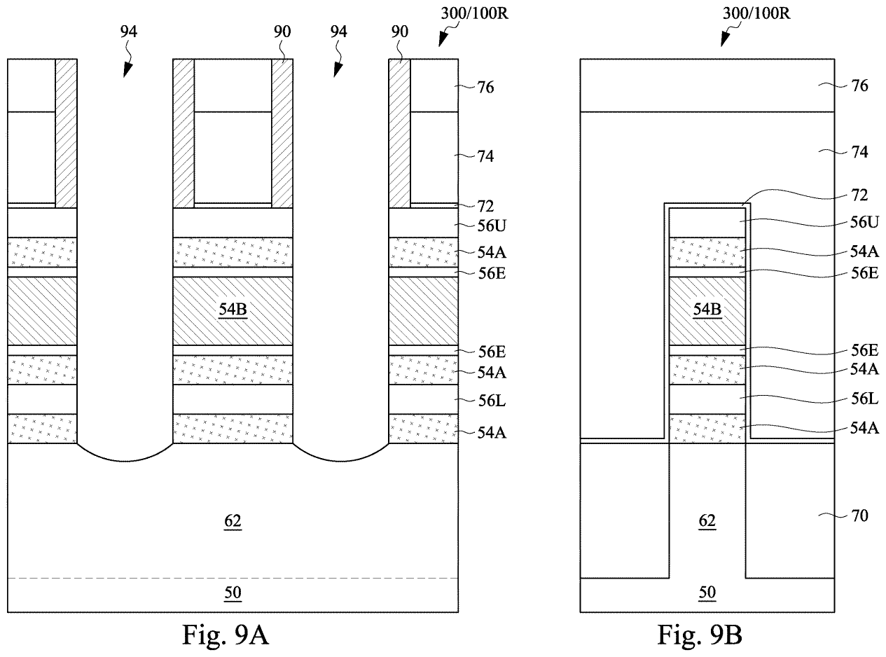

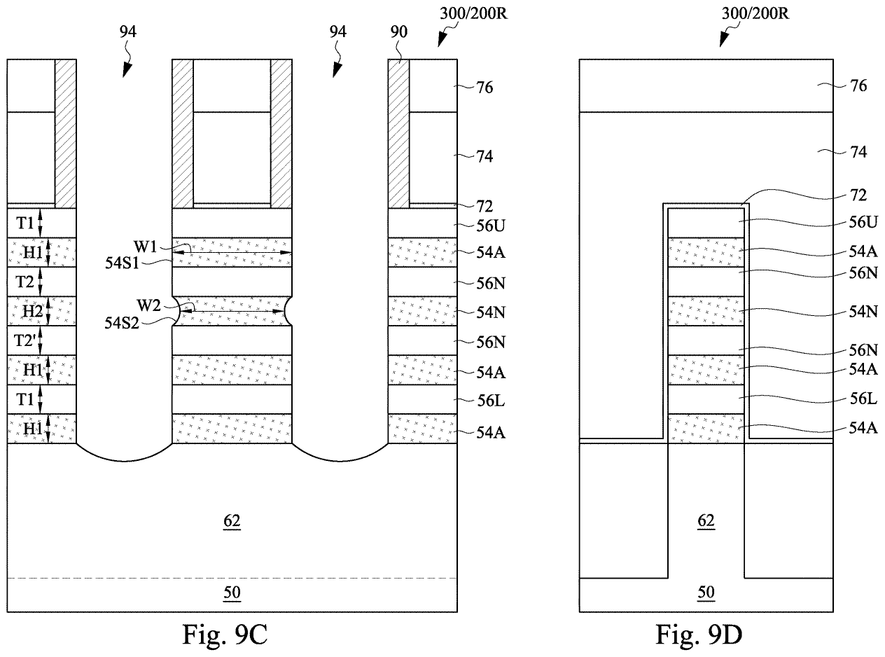

Next, in FIGS. 9A-9D, the mask 91 is removed from the CFET region 100R, e.g., by an etching process. The NSFET region 200R may be covered by, e.g., a patterned photoresist layer during the etching process, such that the mask 91 is removed without etching the NSFET region 200R. The patterned photoresist layer may then be removed by, e.g., an ashing process.

Next, a suitable etching process, such as an anisotropic etching process, is performed to remove portions of the semiconductor materials 54′ and 56′ disposed along the sidewalls and the bottoms of the source/drain recesses 94. After the anisotropic etching process is completed, the remaining portions of the semiconductor materials 54′ within the gaps 95 form dummy nanostructures 54N, and the remaining portions of the semiconductor materials 56′ within the gaps 95 form nanostructures 56N. Nanostructures 56N and nanostructures 56U, 56L together function as the channel regions of the NSFETs formed subsequently. Therefore, the nanostructures 56L, 56U, and 56N are collectively referred to as nanostructures 56 hereinafter. Note that each dummy nanostructure 54N is interposed vertically between two respective nanostructures 56N. A patterned mask layer, such as a patterned photoresist layer, may be used to cover the CFET region 100R during the etching process to remove the semiconductor materials 54′ and 56′. The patterned mask layer may then be removed by a suitable removal process, such as ashing.

Note that depending on, e.g., the thickness of the nanostructures 56E and the thickness of the deposited semiconductor material 56', the thickness of the nanostructures 56N may be different from the thickness of the nanostructures 56U and 56L. For example, the nanostructures 56U and 56L in FIG. 9C may have a same thickness T₁, which is determined by the thickness of the semiconductor layers 66 in FIG. 3. In FIG. 9C, the thicknesses of the nanostructures 56N over and under the dummy nanostructure 54N are denoted as T₂ and T′₂, respectively, where T₂ and T′₂ may or may not be the same. The thickness T₂ (or T′₂) of each of the nanostructures 56N may be the same as, larger than, or smaller than, the thickness of the nanostructures 56. In some embodiments, the thickness T₂ (or T′₂) differs from the thickness T₁ by more than, e.g., 10%, 20%, 30%, or more. In some embodiments, the difference between the thickness T₂ (or T′₂) and the thickness T₁ is between about 0 nm and about 2 nm.

In the example of FIG. 9C, the sidewalls 54S1 of the first dummy nanostructures 54A are straight and are flush with respective sidewalls of the nanostructures 56 (or flush with respective sidewalls of the gate spacers 90). The sidewalls 54S2 of the dummy nanostructure 54N are recessed from respective sidewalls 54S1 of the first dummy nanostructures 54A. For example, the sidewalls 54S2 may curve toward a center of the dummy nanostructure 54N. As a result, a width W₂ of the dummy nanostructure 54N is smaller than a width W₁ of the first dummy nanostructure 54A. The curved shape of the sidewalls 54S2 result in curved sidewalls for the subsequently formed inner spacers 98 (e.g., 98A), and result in a shorter gate length at the location of the dummy nanostructure 54N after the dummy nanostructure 54N is removed and replaced by a replacement gate structure, more details are discussed hereinafter. The shape (e.g., concave shape) of the sidewalls 54S2 in FIG. 9C is merely a non-limiting example. The sidewalls 54S2 may have other shapes, such as a convex shape, or a straight shape (e.g., a linear shape), and may be flush with, protruding from, or recessed from, respective sidewalls of the nanostructures 56.

In addition, as illustrated in FIG. 9C, a distance H₂ between the vertically adjacent nanostructures 56N is different from a distance H₁ between vertically adjacent nanostructures 56, where the distance H₁ is determined by the thickness of the first dummy layers 64A in FIG. 3. For example, the distance H₁ between vertically adjacent nanostructures 56U or 56L (or between the nanostructure 56N and 56U, or between the nanostructures 56N and 56L, or between the nanostructure 56L and the top of the fin 62) may be uniform, and the distance H₂ between vertically adjacent nanostructures 56N may be same as, smaller than, or larger than the distance H₁. In some embodiments, the distance H₂ differs from the distance H₁ by more than, e.g., 10%, 20%, 30%, or more. In some embodiments, the difference between the distance H₂ and the distance H₁ is between about 0 nm and about 2 nm.

Next, in FIGS. 10A-10D, the second dummy nanostructures 54B in the CFET region 100R are removed and replaced by isolation structures 100. A selective etching process, which is same as or similar to the selective etching process for forming the gaps 95 in FIGS. 7C and 7D, may be performed to remove the second dummy nanostructures 54B in the CFET region 100R, thus details are not repeated.

After the second dummy nanostructures 54B in the CFET region 100R are removed, gaps are formed between the nanostructures 56E in the CFET region 100R. In some embodiments, to form the isolation structures 100, a dielectric material 100 is formed (e.g., conformally) to line the bottoms and sidewalls of the source/drain recesses 94, and to fill the gaps between the nanostructures 56E in the CFET region 100R. In some embodiments, the dielectric material 100 is a suitable dielectric material such as silicon oxide, silicon nitride, silicon oxynitride, silicon carbonitride, silicon oxycarbide, aluminum oxide, hufnium oxide, zirconium oxide, the like, combinations thereof, or multiplayers thereof. The dielectric material 100 may be a single layer material, or may comprise a plurality of sub-layers, such as having a bi-layered structure, or a tri-layered structure. A suitable formation method, such as CVD, PVD, ALD, or the like, may be performed to form the dielectric material 100.

Next, an etching process is performed to remove portions of the dielectric material 100 that are disposed outside of the gaps between the nanostructures 56E in the CFET region 100R. The etching process may be anisotropic (e.g., an anisotropic plasma etching process), although a suitable isotropic etching process may also be used. After the etching process, remaining portions of the dielectric material 100 inside the gaps form isolation structures 100 (also referred to as dielectric isolation structures). In some embodiments, the dielectric material 100 is also formed in the source/drain recesses 94 in the NSFET region 200R, and the etching process described above for forming the isolation structures 100 removes the dielectric material 100 formed in the NSFET regions 200R.

In the example of FIG. 10A, sidewalls of the isolation structures 100 are straight and are flush with sidewalls of the nanostructures 56. In other embodiments, the sidewalls of the isolation structures 100 may be curved (e.g., concave, or convex), and/or may not align with the sidewalls of the nanostructures 56. These and other variations are fully intended to be included within the scope of the present disclosure.

Next, inner spacers 98 are formed in both the CFET region 100R and the NSFET region 200R. Forming the inner spacers 98 may include performing an etching process that laterally etches the first dummy nanostructures 54A. The etching process may be isotropic and may be selective to the material of the first dummy nanostructures 54A, so that the first dummy nanostructures 54A are etched at a faster rate than the nanostructures 56. Although sidewalls of the first dummy nanostructures 54A are illustrated as being straight after the etching, the sidewalls may be concave or convex.

The inner spacers 98 are formed on sidewalls of the recessed first dummy nanostructures 54A. As subsequently described in greater detail, source/drain regions will be subsequently formed in the source/drain recesses 94, and the first dummy nanostructures 54A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etching processes, such as the etching processes used to form gate structures. Isolation structures 100, on the other hand, are used to isolate the upper semiconductor nanostructures 56U (collectively) from the lower semiconductor nanostructures 56L (collectively). Further, the isolation structures 100 may define the boundaries of the lower nanostructure FETs and the upper nanostructure FETs.

The inner spacers 98 may be formed by conformally depositing an insulating material in the source/drain recesses 94, and on sidewalls of the recessed first dummy nanostructures 54A, and then etching the insulating material. The insulating material may be a hard dielectric material, e.g., a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining along the sidewalls of the (recessed) first dummy nanostructures 54A (thus forming the inner spacers 98).

The sidewalls of the inner spacers 98 may be flush with sidewalls of the nanostructures 56, or may protrude from or be recessed from the sidewalls of the nanostructures 56. In FIG. 10C, inner spacers 98A, which are interposed between nanostructures 56N, have curved sidewalls due to the curved sidewalls 54S2 of the dummy nanostructure 54N (see FIG. 9C).

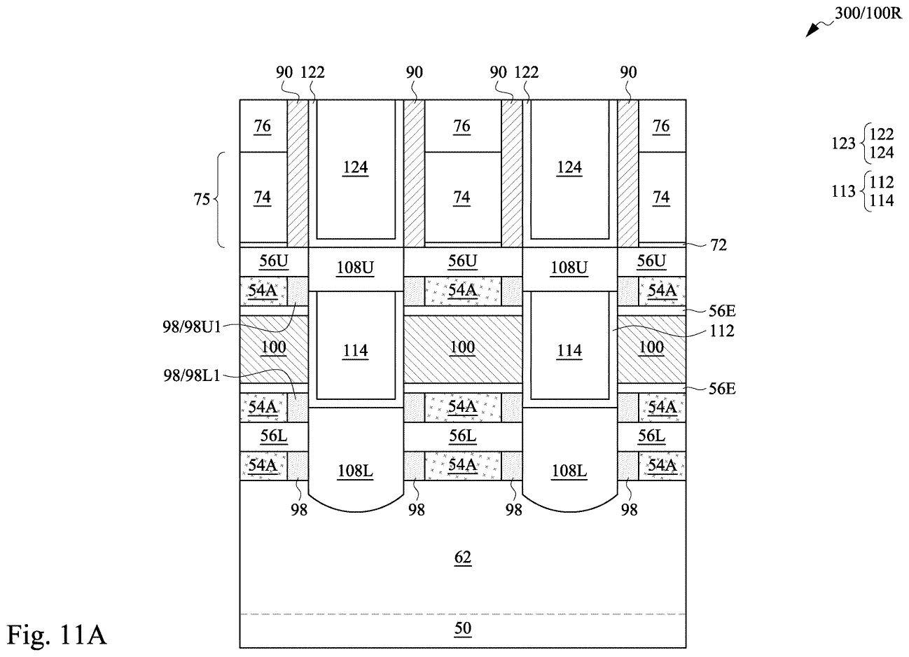

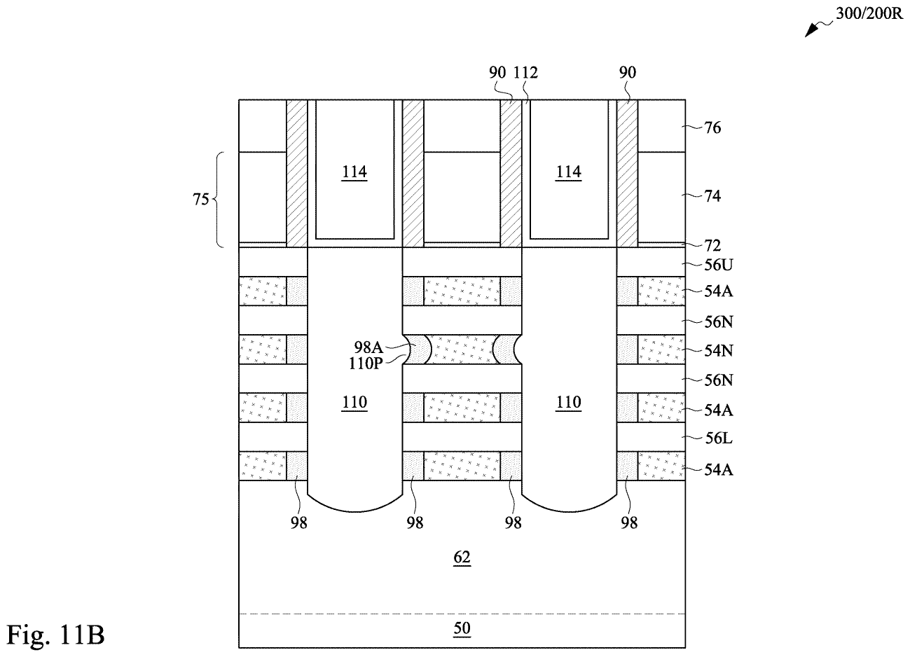

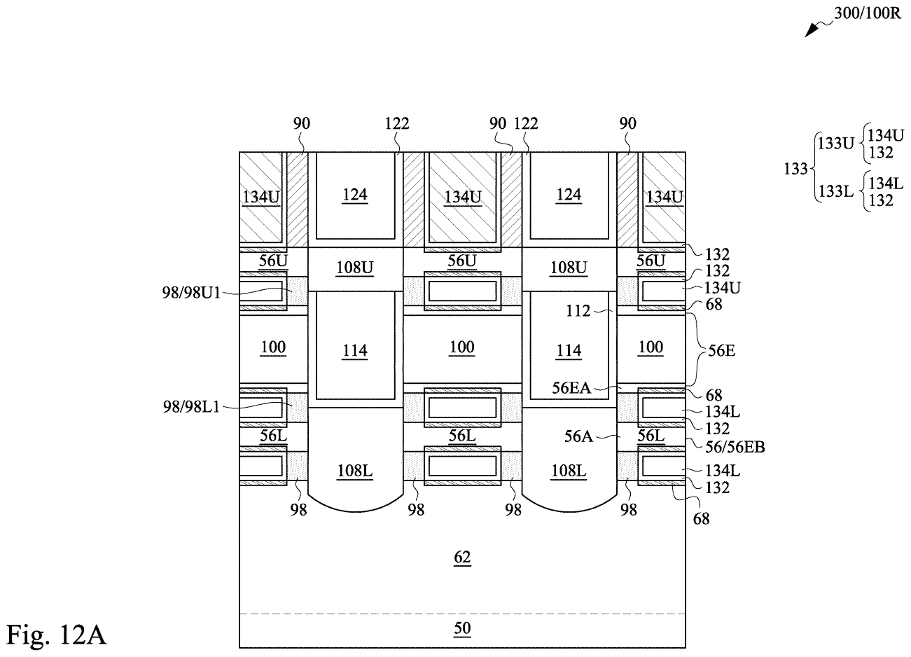

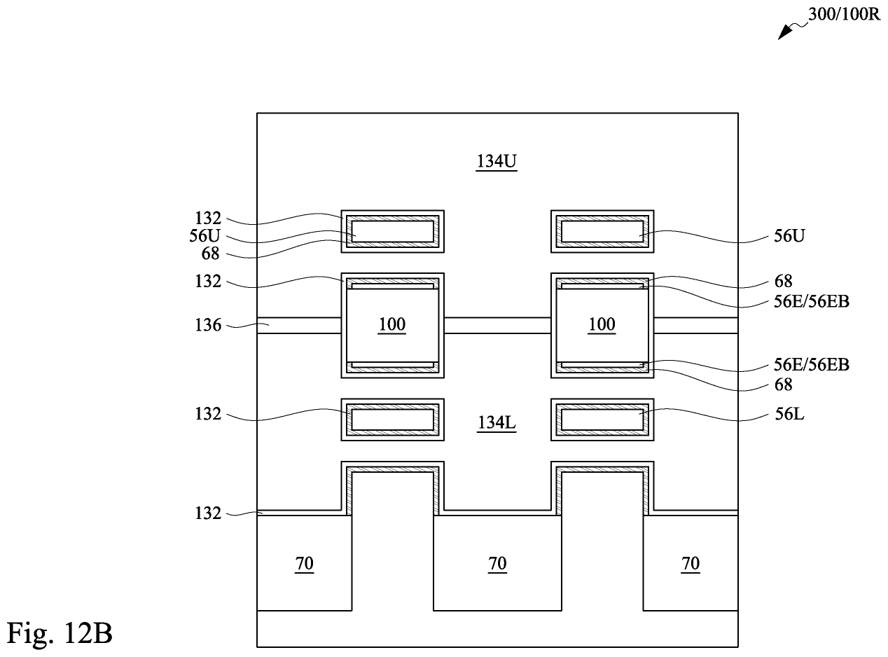

Next, in FIGS. 11A and 11B, lower epitaxial source/drain regions 108L and upper epitaxial source/drain regions 108U are formed in the CFET region 100R, and epitaxial source/drain regions 110 are formed in the NSFET region 200R. In some embodiments, the NSFET region 200R is covered (e.g., by a patterned photoresist layer) while source/drain regions are formed in the CFET region 100R. The patterned photoresist layer is then removed. Similarly, the CFET region 100R is covered (e.g., by a patterned photoresist layer) while source/drain regions are formed in the NSFET region 200R. The patterned photoresist layer is then removed.

As illustrated in FIG. 11A, the lower epitaxial source/drain regions 108L are formed in the lower portions of the source/drain recesses 94 in the CFET region 100R. The lower epitaxial source/drain regions 108L are in contact with the lower semiconductor nanostructures 56L and are not in contact with the upper semiconductor nanostructures 56U. Inner spacers 98 electrically insulate the lower epitaxial source/drain regions 108L from the first dummy nanostructures 54A, which will be replaced with replacement gates in subsequent processes.

The lower epitaxial source/drain regions 108L are epitaxially grown, and have a conductivity type that is suitable for the device type (p-type or n-type) of the lower nanostructure FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 56U may be masked to prevent unintentional epitaxial growth on the upper semiconductor nanostructures 56U. After the lower epitaxial source/drain regions 108L are grown, the masks on the upper semiconductor nanostructures 56U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 54 and 56. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 56U are exposed. The first ILD 114 and the first CESL 112 after the recessing may be collectively referred to as dielectric structures 113. In the illustrated embodiment, the dielectric structures 113 extend along sidewalls of the isolation structures 100, along sidewalls of inner spacers 98U1 (e.g., inner spacers 98 over and closest to the isolation structures 100), and along sidewalls of the inner spacers 98L1 (e.g., inner spacers 98 below and closest to the isolation structures 100). Along the vertical direction of FIG. 11A, each dielectric structure 113 is disposed below the upper surface of the inner spacer 98U1 and above the lower surface of the inner spacer 98L1.

Upper epitaxial source/drain regions 108U are then formed in the upper portions of the source/drain recesses 94 in the CFET region 100R. The upper epitaxial source/drain regions 108U may be epitaxially grown from exposed surfaces of the upper semiconductor nanostructures 56U. The materials of upper epitaxial source/drain regions 108U may be selected from the same candidate group of materials for forming lower epitaxial source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper epitaxial source/drain regions 108U may remain separated after the epitaxy process or may be merged. As discussed above, the lower nanostructure FET and the upper nanostructure FET of the CFET device may be of the same device type (e.g., n-type or p-type), or may be of different device types.

After the upper epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 76 are coplanar (within process variations). The planarization process may leave masks 76 unremoved (as shown), or may remove the masks 76, in which case the top surface of the second ILD 124 is level with the top surface of the dummy gate structures 75. The second ILD 124 and the second CESL 122 after the planarization process may be collectively referred to as dielectric structures 123.

As illustrated in FIG. 11B, epitaxial source/drain regions 110 are epitaxially grown in the source/drain recesses 94 in the NSFET region 200R. The epitaxial source/drain regions 110 have a conductivity type that is suitable for the device type (p-type or n-type) of the NSFETs formed. The material(s) and the formation method(s) for the epitaxial source/drain regions 110 are the same as or similar to those discussed above for the lower epitaxial source/drain regions 108L, thus details are not repeated here. In the example of FIG. 11B, each epitaxial source/drain region 110 has a protrusion 110P that contacts and extends along the curved sidewall of a respective inner spacer 98A.

Next, the first ILD 114 and the first CESL 112 are formed over the epitaxial source/drain regions 110, and a planarization process, such as CMP, is performed next to remove excess portions of the first ILD 114 and the first CESL 112. After the planarization process is finished, the first ILD 114, the first CESL 112, the gate spacers 90, and the mask 76 (if the mask 76 is not removed by the planarization process) have a coplanar upper surface. The planarization process may remove the masks 76, in which case the top surface of the first ILD 114 is level with the top surface of the dummy gate structures 75.

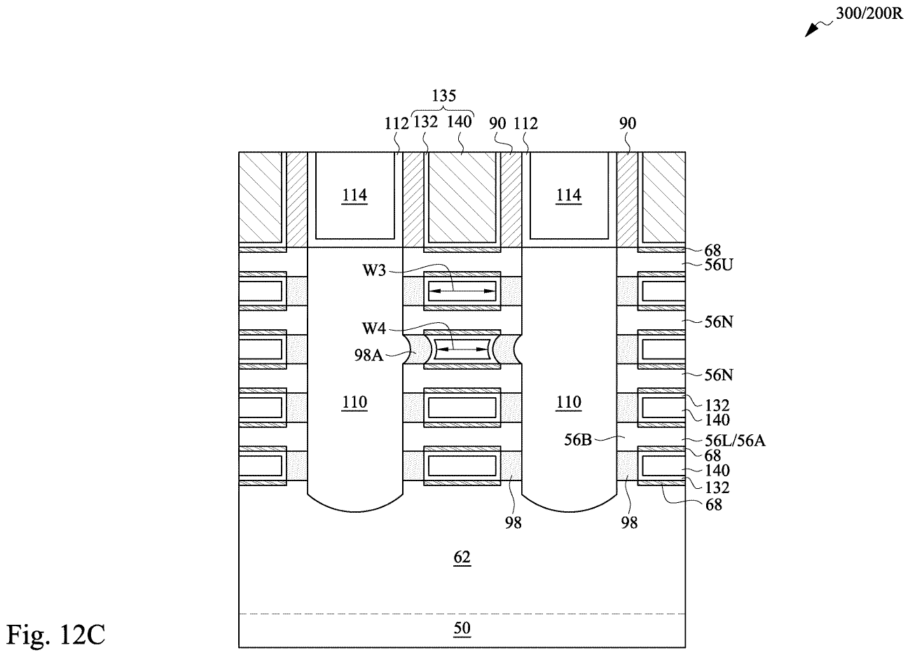

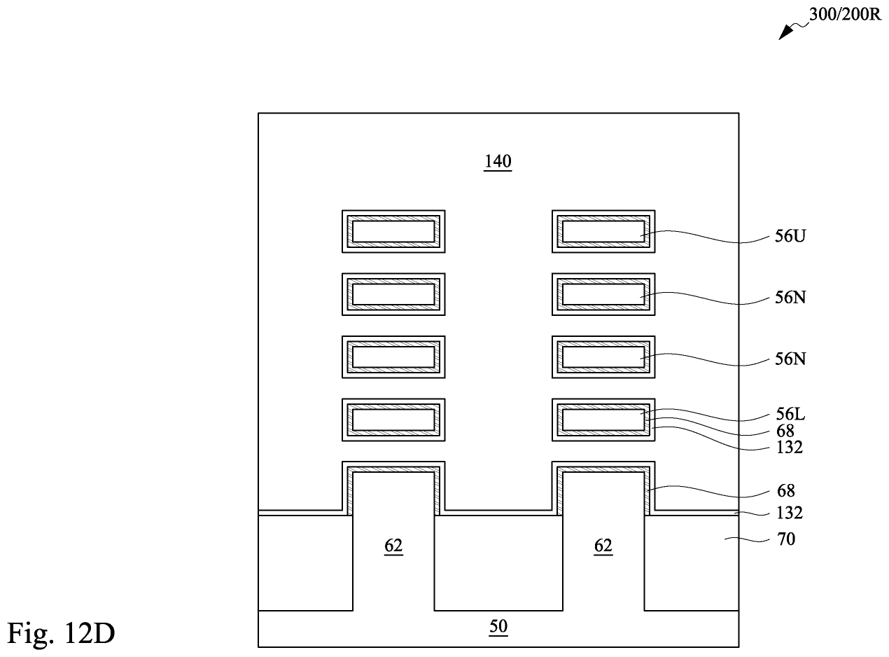

Next, in FIGS. 12A-12D, the dummy gate structures 75 are replaced by replacement gate structures in a replacement gate process. The mask 76 (if not removed already) is removed, e.g., by a CMP process. Next, the dummy gate structures 75 are removed in one or more etching steps, so that recesses are formed between the gate spacers 90. In some embodiments, the dummy gates 74 and the dummy dielectrics 72 are removed by an anisotropic dry etch process. For example, the etching process may include a dry etch process using reaction gas(es) that selectively etch the material of the dummy gates 74. Each of the recesses exposes and/or overlies portions of nanostructures 56 which act as the channel regions in the resulting devices. In the CFET region 100R, the portions of the nanostructures 56 which act as the channel regions are disposed between neighboring pairs of the lower epitaxial source/drain regions 108L or between neighboring pairs of the upper epitaxial source/drain regions 108U. In the NSFET region 200R, the portions of the nanostructures 56 which act as the channel regions are disposed between neighboring pairs of the epitaxial source/drain regions 110. During the removal, the dummy dielectrics 72 may be used as etch stop layers when the dummy gates 74 are etched. The dummy dielectrics 72 may then be removed after the removal of the dummy gates 74.

The remaining portions of the first dummy nanostructures 54A are then removed to form openings (e.g., empty spaces) between the nanostructures 56. The remaining portions of the first dummy nanostructures 54A can be removed by any acceptable etch process that selectively etches the material of the first dummy nanostructures 54A at a faster rate than the materials of the nanostructures 56, the inner spacers 98, and the isolation structures 100. The etching may be isotropic. For example, when the first dummy nanostructures 54A are formed of silicon-germanium, the semiconductor nanostructures 56 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trimming process (not separately illustrated) is performed to decrease the thicknesses of the exposed portions of the nanostructures 56 and expand the distance between vertically adjacent channel regions (e.g., nanostructures 56).

Next, an interfacial layer 68 is formed at the exterior surfaces of the nanostructures 56. In some embodiments, the interfacial layer 68 is formed of an oxide of a group II-VI material or an oxide of a group IV material. In the illustrated embodiment, the interfacial layer 68 is an oxide of the material of the nanostructures 56, and is formed by an oxidization process (e.g., a thermal oxidization process). In other words, the interfacial layer 68 is formed by converting (e.g., oxidizing) exterior portions of the nanostructures 56 into an oxide (e.g., silicon oxide) of the material (e.g., silicon) of the nanostructures 56. In the illustrated embodiment, the oxidization process also converts exterior portions of the nanostructures 56E and the fins 62 into the interfacial layer 68. Note that in FIG. 12A, the interfacial layer 68 is formed at surfaces of middle portions 56B of the nanostructures 56, and no interfacial layer 68 is formed at surfaces of end portions 56A of the nanostructures 56, which end portions 56A are disposed between vertically adjacent inner spacers 98. This is because the end portions 56A are not exposed to the openings between vertically adjacent nanostructures 56, thus not oxidized by the oxidization process. Similarly, no interfacial layer is formed at surfaces of end portions 56EA of the nanostructures 56E.

In the cross-sectional view of FIG. 12B, the interfacial layer 68 surrounds (e.g., encircles) the nanostructures 56. In some embodiments, no interfacial layer 68 is formed along sidewalls of the isolation structures 100, due to the oxidization process used for forming the interfacial layer 68. Notably, in FIG. 12B, the interfacial layer 68 surrounds three sidewalls of each nanostructure 56E and forms a U-shape. The fourth sidewall of each nanostructure 56E contacts and extends along the isolation structure 100, thus is not oxidized.

Still referring to FIGS. 12A-12D, next, a gate dielectric layer 132 (also referred to as gate dielectrics) is formed (e.g., conformally) over the interfacial layer 68 and along sidewalls of the isolation structures 100 (see FIG. 12B), such that the gate dielectric layer 132 conformally lines the recesses between gate spacers 90 and lines the openings between the nanostructures 56. Specifically, the gate dielectric layer 132 is formed on the top surfaces of the fins 62; along the top surfaces, the sidewalls, and the bottom surfaces of the nanostructures 56 (on the interfacial layer 68); along the top surfaces, the sidewalls, and the bottom surfaces of the isolation structures 100; and along the sidewalls of the gate spacers 90. The gate dielectric layer 132 wraps around all (e.g., four) sides of the nanostructures 56 and the isolation structures 100. The gate dielectric layer 132 may also be formed on the top surfaces of first ILD 114, the second ILD 124, and the gate spacers 90, and may be formed along the sidewalls of the fins 62 (e.g., in embodiments where the top surfaces of the isolation regions 70 are below the top surfaces of the fins 62).

The gate dielectric layer 132 may include an oxide such as silicon oxide or a metal oxide, a silicate such as a metal silicate, combinations thereof, multi-layers thereof, or the like. The gate dielectric layer 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 132 may include molecular-beam deposition (MBD), ALD, PECVD, and the like.

Next, in the CFET region 100R, lower gate electrodes 134L are formed on the gate dielectrics 132 around the lower nanostructures 56L. For example, the lower gate electrodes 134L wrap around the lower nanostructures 56L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a gate fill material (e.g., a metal or metal-containing material).

The lower gate electrodes 134L are formed of material(s) that are suitable for the device type of the lower nanostructure FETs. For example, the lower gate electrodes 134L may include one or more work function tuning layer(s) formed of material(s) that are suitable for the device type of the lower nanostructure FETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally, or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 134L may be formed by conformally depositing one or more gate electrode layer(s), then recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 134L may expose the upper semiconductor nanostructures 56U.

In some embodiments, isolation layers 136 (see FIG. 12B) may be optionally formed on the lower gate electrodes 134L. The isolation layers 136 act as isolation features between the lower gate electrodes 134L and subsequently formed upper gate electrodes 134U. The isolation layers 136 may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 56U.

Next, upper gate electrodes 134U are formed on the isolation layers 136 described above (if present) or on the lower gate electrodes 134L. The upper gate electrodes 134U are disposed between the upper nanostructures 56U, and wrap around the upper nanostructures 56U. The upper gate electrodes 134U may be formed of the same candidate materials and candidate processes for forming the lower gate electrodes 134L. The upper gate electrodes 134U are formed of material(s) that are suitable for the device type of the upper nanostructure FETs. For example, the upper gate electrodes 134U may include one or more work function tuning layer(s) formed of material(s) that are suitable for the device type of the upper nanostructure FETs. Although single-layered gate electrodes 134U are illustrated, the upper gate electrodes 134U may include any number of work function tuning layers, any number of barrier layers, any number of glue layers, and a gate fill material.

Additionally, a removal process is performed to level top surfaces of the upper gate electrodes 134U and the second ILD 124. In some embodiments, a planarization process such as a CMP, an etch-back process, combinations thereof, or the like may be utilized as the removal process. After the planarization process, the top surfaces of the upper gate electrodes 134U, the gate dielectrics 132, the second ILD 124, and the gate spacers 90 are substantially coplanar (within process variations) in the CFET region 100R. Each respective pair of a gate dielectric 132 and a gate electrode 134 (including an upper gate electrode 134U and/or a lower gate electrode 134L) may be collectively referred to as a “gate structure” 133 (including upper gate structures 133U and lower gate structures 133L). Each gate structure 133 (may also be referred to as a replacement gate structure, or a metal gate structure) extends along multiple sides (e.g., a top surface, sidewalls, and a bottom surface) of a channel region of a nanostructure 56. The lower gate electrode 134L may also extend along sidewalls and/or a top surface of a fin 62.

In the NSFET region 200R, replacement gate structures 135 are formed by forming gate electrodes 140 on the gate dielectrics 132 around the nanostructures 56. For example, the gate electrodes 140 wrap around the nanostructures 56. The gate electrodes 140 may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the gate electrodes 140 may include any number of work function tuning layers, any number of barrier layers, any number of glue layers, and a gate fill material (e.g., a metal or metal-containing material). The gate electrode 140 may be formed using the same or similar processing describe above for the lower gate electrodes 134L, thus details are not repeated here. A planarization process may be performed to achieve a coplanar upper surface between the gate electrodes 140, the gate dielectrics 132, the gate spacers 90, and the first ILD 114 in the NSFET region 200R. Skilled artisans will readily appreciate that the upper surfaces of the replacement gate structures 133, the gate spacers 90, and the second ILD 124 in the CFET region 100R are level with the upper surfaces of the replacement gate structures 135, the gate spacers 90, and the first ILD 114 in the NSFET region 200R, in some embodiments.

In the example of FIG. 12C, the replacement gate structure 135 (which includes the gate dielectric 132 and the gate electrode 140) has a width W₄ at the location of the dummy structure 54N (see FIG. 9C), and has a width W₃ at the location of the first dummy structure 54A (see FIG. 9C). The width W₄ is smaller than the width W₃, due to the smaller width W₂ of the dummy structure 54N. Note that due to the curved sidewalls of the spacers 98A, the replacement gate structure 135 also has curved sidewalls at the locations of the inner spacers 98A.

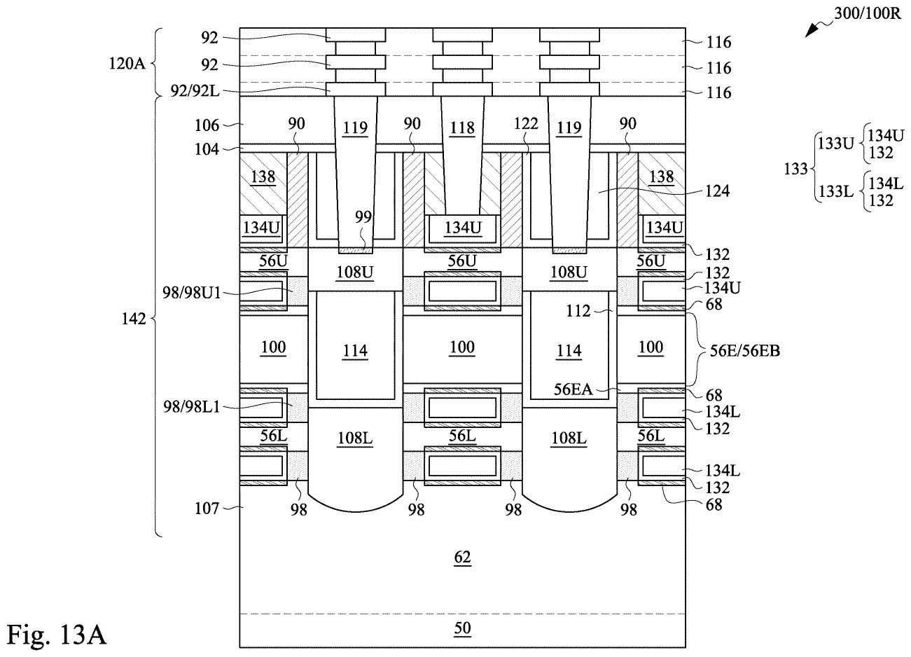

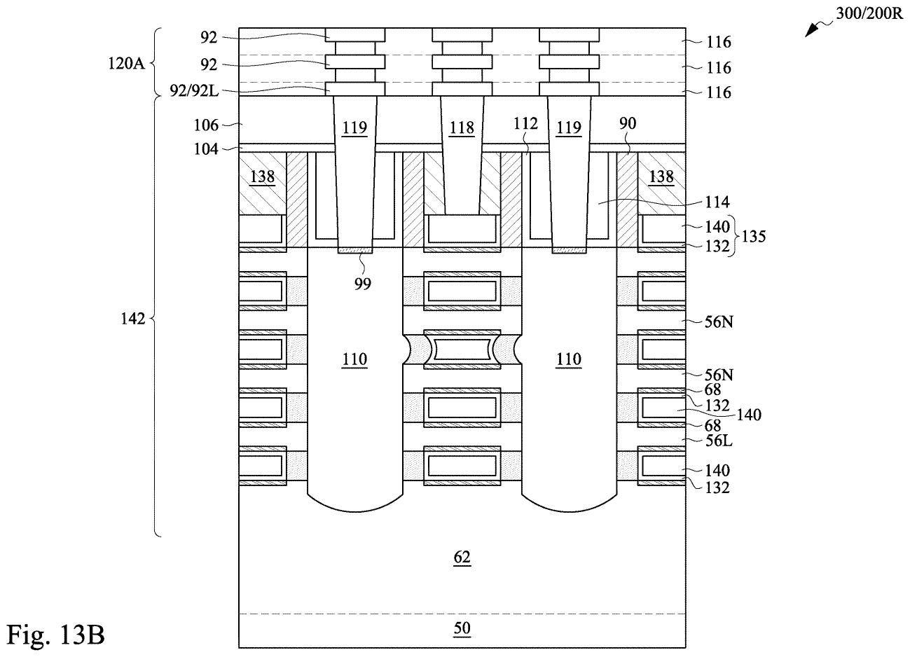

Next, in FIGS. 13A and 13B, gate masks 138 are formed over the replacement gate structures 133 in the CFET region 100R and over the replacement gate structures 135 in the NSFET region 200R. The formation process may include recessing replacement gate structures 133 and 135, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 124 in the CFET region 100R and over the first ILD 114 in the NSFET region 200R.

Next, an etch stop layer (ESL) 104 and a third ILD 106 are formed over the first ILD 114 (in the NSFET region 200R), the second ILD 124 (in the CFET region 100R), and the gate masks 138. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Next, in the CFET region 100R, source/drain contact openings are formed to extend through the ESL 104, the third ILD 106, the second ILD 124 and the second CESL 122 to expose the upper epitaxial source/drain regions 108U. Similarly, gate contact openings are formed to extend through the ESL 104, the third ILD 106, and the gate masks 138 to expose the upper gate electrode 134U. Next, silicide regions 99 are formed on the upper epitaxial source/drain regions 108U, and source/drain contact plugs 119 are formed on the silicide regions 99 to electrically couple to the upper epitaxial source/drain regions 108U. In addition, gate contact plugs 118 are formed in the gate contact openings to electrically couple to the upper gate electrode 134U.

In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the upper epitaxial source/drain regions 108U, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, ruthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings.

As illustrated in FIG. 13B, in the NSFET region 200R, the source/drain contact plugs 119 and the gate contact plugs 118 are formed, using the same or similar processing for forming the source/drain contact plugs 119 and the gate contact plugs 118 in the CFET region 100R. In some embodiments, the source/drain contact plugs 119 and the gate contact plugs 118 in both the CFET region 100R and the NSFET region 200R are formed at the same time using the same processing steps.

In FIGS. 13A and 13B, the layers of the semiconductor device 300 disposed between upper portions of the fins 62 and the third ILD 106 are collectively referred to as the device layer 142 of the semiconductor device 300.

Next, a front-side interconnect structure 120A is formed on the device layer 142. The front-side interconnect structure 120A includes dielectric layers 116 and layers of conductive features 92 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 92 may include conductive lines and vias, which may be formed using, e.g., damascene processes. Conductive features 92 may include metal lines and vias, which may include diffusion barriers and a copper containing material over the diffusion barriers. There may also be aluminum pads over and electrically connected to the metal lines and vias. Depending on how the respective die is to be packaged, the top surface features among the conductive features 92 may include bond pads, metal pillars, solder regions, and/or the like.

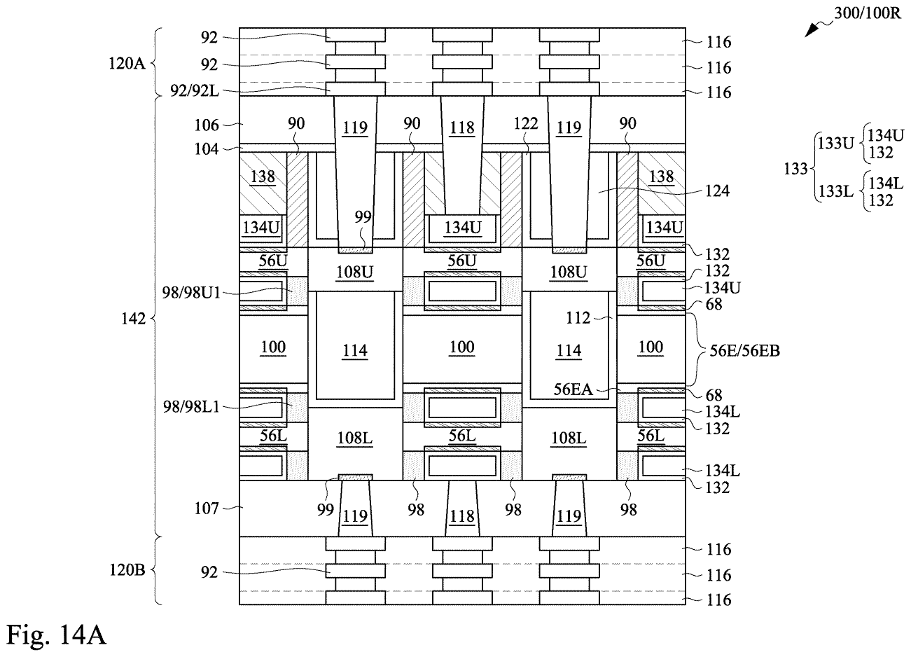

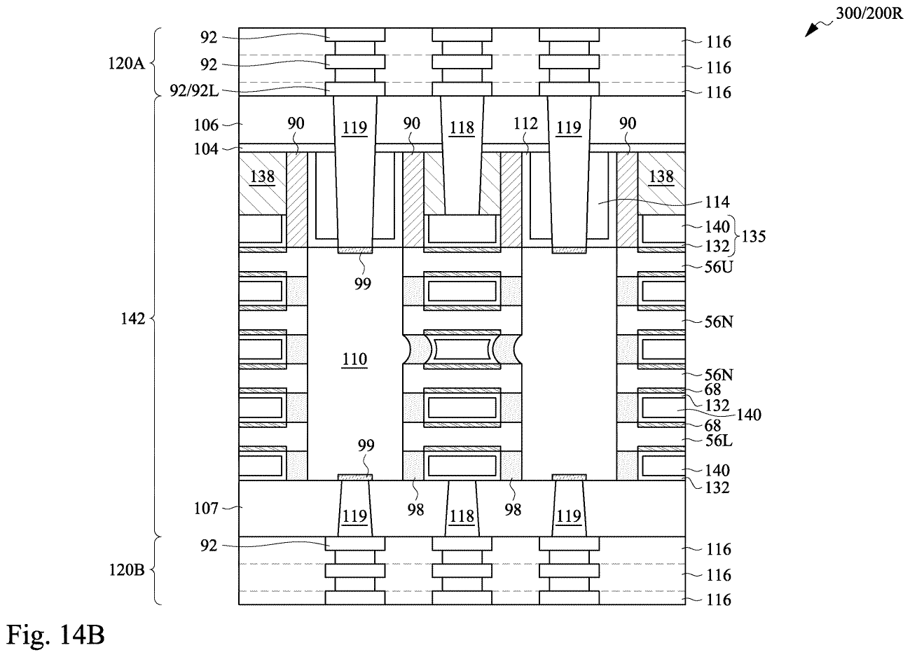

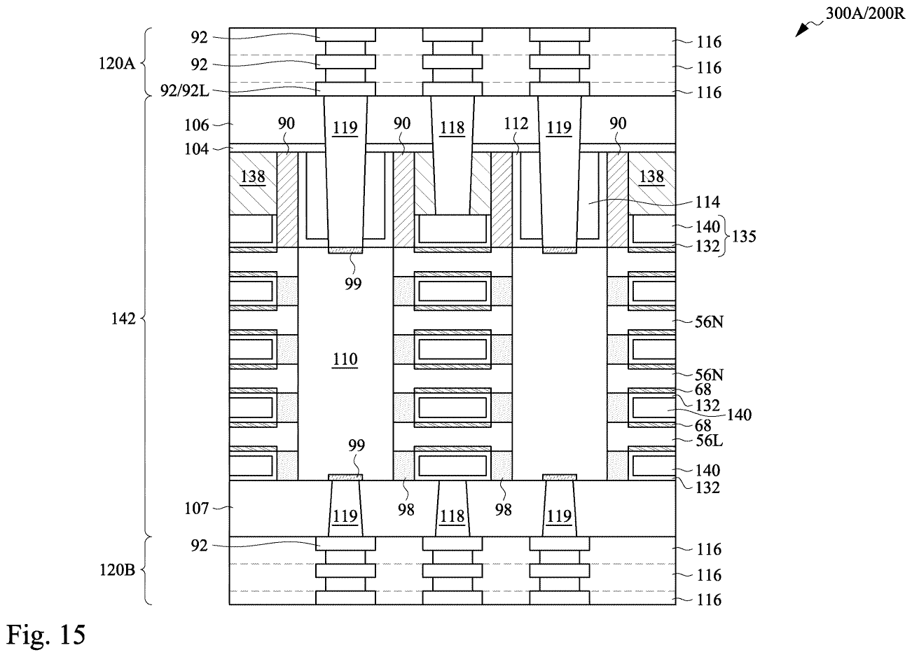

FIGS. 14A and 14B illustrated additional processing, which is optional, to form a backside interconnect structure 120B. In FIGS. 14A and 14B, a carrier (not shown) is attached to the front-side interconnect structure 120A. The carrier may be, e.g., a glass carrier, a silicon carrier, or the like. Next, a backside thinning process is performed to remove the substrate 50 and at least lower portions of the fins 62. The backside thinning process also removes (e.g., completely removes) the isolation regions 70, in some embodiments. The backside thinning process may be, e.g., a CMP process, an etch back process, combinations thereof, or the like. In some embodiments, top portions of the fins 62 remain after the backside thinning process. In some embodiments, the fins 62 are completely removed after the backside thinning process. These and other variations are fully intended to be included within the scope of the present disclosure.

Next, a fourth ILD 107 is formed on the lower epitaxial source/drain regions 108L (in the CFET region 100R) and on the backside of the epitaxial source/drain region 110 (in the NSFET region 200R). The fourth ILD 107 may be the same as the third ILD 106, and may be formed by a same or similar formation method, thus details are not repeated.

Next, source/drain contact plugs 119 and gate contact plugs 118 are formed in the fourth ILD 107 to electrically couple to the lower epitaxial source/drain regions 108L and the lower gate structures 133L, respectively, in the CFET region 100R. Similarly, source/drain contact plugs 119 and gate contact plugs 118 are formed in the fourth ILD 107 to electrically couple to the epitaxial source/drain regions 110 and the replacement gate structures 135 in the NSFET region 200R. Silicide regions 99 may be formed between the source/drain contact plugs 119 and the respective source/drain regions (e.g., 108L or 110). In the example of FIGS. 14A and 14B, the layers of the semiconductor device 300 disposed between the third ILD 106 and the fourth ILD 107 are collectively referred to as the device layer 142 of the semiconductor device 300.

Next, the backside interconnect structure 120B is formed on the fourth ILD 107. The backside interconnect structure 120B comprises dielectric layers 116 and conductive features 92 (e.g., metal lines or vias) formed in the dielectric layer 116. The backside interconnect structure 120B may be formed by a same or similar formation method as the front-side interconnect structure 120A, thus details are not repeated here.

Additional processing may be performed to completer the fabrication of the semiconductor device 300, as skilled artisans readily appreciate. For example, a dicing process may be performed to separate multiple semiconductor devices 300 formed on the substrate 50 (e.g., a wafer) into separate (e.g., individual) semiconductor devices 300. Details are not discussed here. Each individual semiconductor device 300 includes a CFET device (formed in the CFET region 100R) and an NSFET device (formed in the NSFET region 200).

FIG. 15 a cross-sectional view of a semiconductor device 300A, in accordance with another embodiment. The semiconductor device 300A is similar to the semiconductor device 300, but a portion of the replacement gate structure 135 between vertically adjacent nanostructures 56N has straight sidewalls instead of the curved sidewalls as shown in the semiconductor device 300, and the width of the portion of the replacement gate structure 135 between the vertically adjacent nanostructures 56N may the same as the width of other portions of the replacement gate structure 135. The shape and the width of the portion of the replacement gate structures 135 between vertically adjacent nanostructures 56N are determined by how the semiconductor materials 56′ and 54′ fill the gaps 95 (see FIG. 8C), as discussed above. Note that FIG. 15 shows the NSFET region 200R of the semiconductor device 300A. The cross-sectional view of the semiconductor device 300A in the CFET region 100R is the same as that of the semiconductor device 300 in FIG. 14A, in some embodiments.

Variations to the disclosed embodiments are possible and are fully intended to be included within the scope of the present disclosure. For example, the front-side interconnect structures 120A may be omitted, and only backside interconnect structure 120B is formed. Alternatively, the backside interconnect structures 120B may be omitted, and only the front-side interconnect structure 120A is formed. In embodiments where only the front-side interconnect structure 120A or only the backside interconnect structure 120B is formed, some of the source/drain contact plugs 119 in the CFET region 100R may extend through the dielectric structure 113 to be electrically coupled to both the upper epitaxial source/drain regions 108U and the lower epitaxial source/drain regions 108L.

Advantages are achieved by the disclosed embodiments. Complementary FET (CFET) structures, by stacking devices in bottom and top layers of the semiconductor device, offer promising potential for advanced logic technology due to the ability to achieve high transistor integration density. However, for certain special cells (e.g., unipolar cells), only PFET or NFET is needed. In addition, in certain types of high-performance cells, a large effective width (more numbers of nanosheets or wider widths for nanosheets) is required to generate high driving current, which high driving current may be achieved by using NSFETs. The structures and process flows disclosed herein allow for the coexistence of CFETs and NSFETs in the same semiconductor die. As a result, unipolar cells or high-performance cells can utilize the NSFET region to meet their performance requirements (e.g., high driving current), while the CFET regions offers high integration density for, e.g., advanced logic circuits. The disclosed embodiments help to advance the development of CFET technology and enable the creation of more efficient and powerful semiconductor devices. In addition, the disclosed process flow can be easily integrated into current process flow for forming NSFET devices.

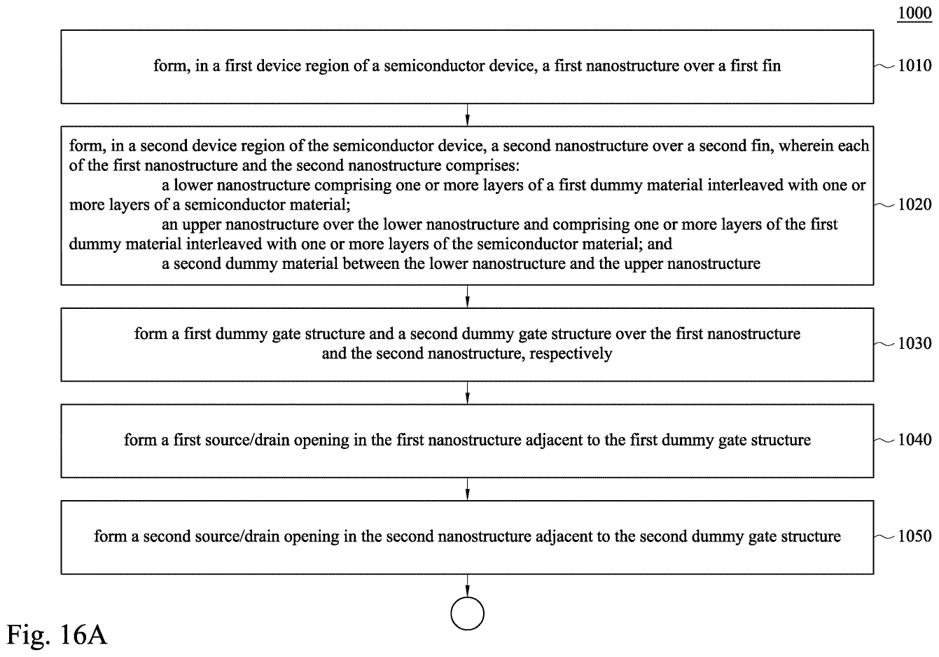

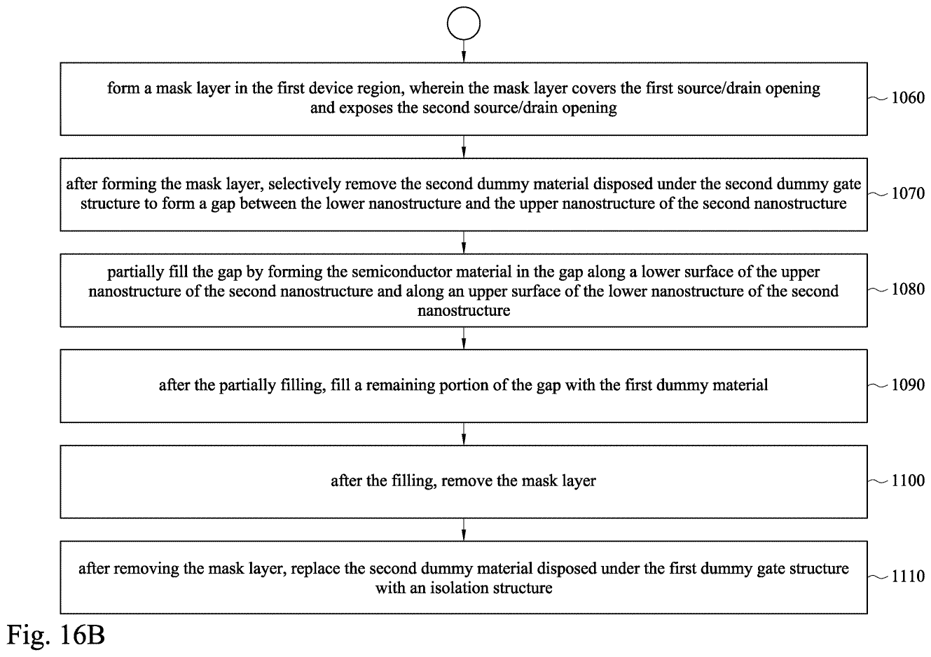

FIGS. 16A and 16B together illustrate a flow chart of a method 1000 of forming a semiconductor device, in accordance with some embodiments. It should be understood that the embodiment method shown in FIGS. 16A and 16B is merely an example of many possible embodiment methods. One of ordinary skill in the art would recognize many variations, alternatives, and modifications. For example, various steps as illustrated in FIGS. 16A and 16B may be added, removed, replaced, rearranged, or repeated.

Referring to FIGS. 16A and 16B, at block 1010, a first nanostructure is formed over a first fin in a first device region of the semiconductor device. At block 1020, a second nanostructure is formed over a second fin in a second device region of the semiconductor device, wherein each of the first nanostructure and the second nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. At block 1030, a first dummy gate structure and a second dummy gate structure are formed over the first nanostructure and the second nanostructure, respectively. At block 1040, a first source/drain opening is formed in the first nanostructure adjacent to the first dummy gate structure. At block 1050, a second source/drain opening is formed in the second nanostructure adjacent to the second dummy gate structure. At block 1060, a mask layer is formed in the first device region, wherein the mask layer covers the first source/drain opening and exposes the second source/drain opening. At block 1070, after forming the mask layer, the second dummy material disposed under the second dummy gate structure is selectively removed to form a gap between the lower nanostructure and the upper nanostructure of the second nanostructure. At block 1080, the gap is partially filled by forming the semiconductor material in the gap along a lower surface of the upper nanostructure of the second nanostructure and along an upper surface of the lower nanostructure of the second nanostructure. At block 1090, after the partially filling, a remaining portion of the gap is filled with the first dummy material. At block 1100, after the filling, the mask layer is removed. At block 1110, after removing the mask layer, the second dummy material disposed under the first dummy gate structure is replaced with an isolation structure.

In an embodiment, a method of forming a semiconductor device includes: forming, in a first device region of the semiconductor device, a first nanostructure over a first fin, and forming, in a second device region of the semiconductor device, a second nanostructure over a second fin, where each of the first nanostructure and the second nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. The method further includes: forming a first dummy gate structure and a second dummy gate structure over the first nanostructure and the second nanostructure, respectively; forming a first source/drain opening in the first nanostructure adjacent to the first dummy gate structure; forming a second source/drain opening in the second nanostructure adjacent to the second dummy gate structure; forming a mask layer in the first device region, wherein the mask layer covers the first source/drain opening and exposes the second source/drain opening; after forming the mask layer, selectively removing the second dummy material disposed under the second dummy gate structure to form a gap between the lower nanostructure and the upper nanostructure of the second nanostructure; partially filling the gap by forming the semiconductor material in the gap along a lower surface of the upper nanostructure of the second nanostructure and along an upper surface of the lower nanostructure of the second nanostructure; after the partially filling, filling a remaining portion of the gap with the first dummy material; after the filling, removing the mask layer; and after removing the mask layer, replacing the second dummy material disposed under the first dummy gate structure with an isolation structure. In an embodiment, the method of further includes, after replacing the second dummy material, forming source/drain regions in the first source/drain opening and the second source/drain opening by: sequentially forming a lower source/drain region, a dielectric structure, and an upper source/drain region in the first source/drain opening; and filling the second source/drain opening by forming a source/drain region in the second source/drain opening. In an embodiment, the method further includes, after forming the source/drain regions: replacing the first dummy gate structure with a first replacement gate structure; and replacing the second dummy gate structure with a second replacement gate structure. In an embodiment, wherein replacing the first dummy gate structure comprises: removing the first dummy gate structure; selectively removing the first dummy material in the first nanostructure, wherein after selectively removing the first dummy material in the first nanostructure, the semiconductor material in the lower nanostructure of the first nanostructure remains and forms first lower channel regions, and the semiconductor material in the upper nanostructure of the first nanostructure remains and forms first upper channel regions; forming a gate dielectric material round the first lower channel regions and the first upper channel regions; forming a first lower gate electrode around the gate dielectric material and the first lower channel regions; and forming a first upper gate electrode around the gate dielectric material and the first upper channel regions. In an embodiment, the method further includes forming an isolation layer between the first lower gate electrode and the first upper gate electrode. In an embodiment, replacing the second dummy gate structure comprises: removing the second dummy gate structure; selectively removing the first dummy material in the second nanostructure, wherein after selectively removing the first dummy material in the second nanostructure, the semiconductor material in the second nanostructure and the semiconductor material formed in the gap remain and form second channel regions; forming the gate dielectric material round the second channel regions; and forming a second gate electrode around the gate dielectric material and the second channel regions. In an embodiment, each of the first nanostructure and the second nanostructure further comprises: a first etch stop layer (ESL) between the lower nanostructure and the second dummy material; and a second ESL between the upper nanostructure and the second dummy material, wherein the first ESL and the second ESL are formed of the semiconductor material, and wherein the first ESL and the second ESL are thinner than the second dummy material. In an embodiment, partially filling the gap comprises epitaxially growing the semiconductor material on an upper surface of the first ESL facing the gap and on a lower surface of the second ESL facing the gap. In an embodiment, the method further includes, after replacing the second dummy material and before forming the source/drain regions: replacing end portions of the first dummy material of the first nanostructure exposed by the first source/drain opening with first inner spacers; and replacing end portions of the first dummy material of the second nanostructure exposed by the second source/drain opening with second inner spacers. In an embodiment, after forming the source/drain regions, the dielectric structure extends along a sidewall of the isolation structure, along a first sidewall of a first inner spacer of the first inner spacers, and along a second sidewall of a second inner spacer of the first inner spacers, wherein the first inner spacer is below the isolation structure and contacts the first ESL, and the second inner spacer is above the isolation structure and contacts the second ESL, wherein the dielectric structure is disposed vertically between an upper surface of the second inner spacer distal from the first fin and a lower surface of the first inner spacer facing the first fin. In an embodiment, the first dummy material and the second dummy material are formed of semiconductor materials with different compositions.

In an embodiment, a method of forming a semiconductor device includes forming, in a first device region of the semiconductor device, a nanostructure field-effect transistor (NSFET), comprising: forming a first nanostructure over a first fin, wherein the first nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. Forming the NSFET further comprises: forming a first dummy gate structure over the first nanostructure; forming a first source/drain opening in the first nanostructure adjacent to the first dummy gate structure; selectively removing the second dummy material disposed under the first dummy gate structure to form a gap between the lower nanostructure and the upper nanostructure of the first nanostructure; partially filling the gap by forming the semiconductor material in the gap; after partially filling the gap, filling a remaining portion of the gap with the first dummy material; after filling the remaining portion of the gap, forming a first source/drain region in the first source/drain opening; and after forming the first source/drain region, replacing the first dummy gate structure with a first replacement gate structure. In an embodiment, partially filling the gap comprises epitaxially growing the semiconductor material along exterior surfaces of the upper nanostructure of the first nanostructure and along exterior surfaces of the lower nanostructure of the first nanostructure. In an embodiment, the epitaxially grown semiconductor material extends into the first source/drain opening, wherein the method further comprises, after filling the remaining portion of the gap and before forming the first source/drain region, performing an anisotropic etching process to remove portions of the epitaxially grown semiconductor material from the first source/drain opening. In an embodiment, after performing the anisotropic etching process, remaining portions of the epitaxially grown semiconductor material form a first layer of the semiconductor material and a second layer of the semiconductor material, wherein the first dummy material disposed between the first layer of the semiconductor material and the second layer of the semiconductor material have first sidewalls, wherein the first sidewalls are recessed from respective sidewalls of the first layer of the semiconductor material and respective sidewalls of the second layer of the semiconductor material. In an embodiment, the method further includes: forming, in a second device region of the semiconductor device, a complementary field-effect transistor (CFET), comprising: forming a second nanostructure over a second fin, wherein the second nanostructure has a same structure as the first nanostructure; forming a second dummy gate structure over the second nanostructure; forming a second source/drain opening in the second nanostructure adjacent to the second dummy gate structure; replacing the second dummy material disposed under the second dummy gate structure with an isolation structure; after replacing the second dummy material, forming a second source/drain region by sequentially forming a lower source/drain region, a dielectric structure, and an upper source/drain region in the second source/drain opening; and after forming the second source/drain region, replacing the second dummy gate structure with a second replacement gate structure. In an embodiment, replacing the second dummy gate structure comprises: selectively removing the first dummy material in the second nanostructure, wherein after selectively removing the first dummy material in the second nanostructure, the semiconductor material of the lower nanostructure of the second nanostructure remains and forms lower channel regions, and the semiconductor material of the upper nanostructure of the second nanostructure remains and forms upper channel regions; forming a gate dielectric material round the lower channel regions and the upper channel regions; forming a lower gate electrode around the gate dielectric material and the lower channel regions; and forming an upper gate electrode around the gate dielectric material and the upper channel regions.

In an embodiment, a semiconductor device includes a substrate and a complementary field-effect transistor (CFET) device over a first region of the substrate, the CFET device comprising: a first fin over the substrate; a first plurality of channel regions disposed vertically over the first fin; a second plurality of channel regions disposed vertically over the first plurality of channel regions; an isolation structure between the first plurality of channel regions and the second plurality of channel regions; first source/drain regions at opposing ends of the first plurality of channel regions; second source/drain regions at opposing ends of the second plurality of channel regions; a dielectric structure between the first source/drain regions and the second source/drain regions; a first gate structure around the first plurality of channel regions; and a second gate structure around the second plurality of channel regions. The semiconductor device further includes a nanostructure field-effect transistor (NSFET) device over a second region of the substrate, the NSFET device comprising: a second fin over the substrate; a third plurality of channel regions disposed vertically over the second fin, wherein an uppermost channel region of the third plurality of channel regions is at a same vertical distance from the substrate as an uppermost channel region of the second plurality of channel regions; third source/drain regions at opposing ends of the third plurality of channel regions; and a third gate structure around the third plurality of channel regions. In an embodiment, the first plurality of channel regions have a uniform distance in-between, the second plurality of channel regions have a uniform distance in-between, and the third plurality of channel regions have a non-uniform distance in-between. In an embodiment, the third plurality of channel regions comprises first channel layer, a second channel layer, and a third channel layer, wherein the second channel layer is between the first channel layer and the third channel layer, wherein the first channel layer and the third channel layer have a same thickness, wherein the second channel layer has a different thickness from the first channel layer and the third channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a complementary field-effect transistor (CFET) device over a first region of the substrate, the CFET device comprising:
a first fin over the substrate;
one or more first channel layers disposed vertically over the first fin;
one or more second channel layers disposed vertically over the one or more first channel layers;
an isolation structure between the one or more first channel layers and the one or more second channel layers;
a first gate structure around the one or more first channel layers; and
a second gate structure around the one or more second channel layers; and
a nanostructure field-effect transistor (NSFET) device over a second region of the substrate, the NSFET device comprising:
a second fin over the substrate;
third channel layers disposed vertically over the second fin; and
a third gate structure around the third channel layers,
wherein an upper surface of an uppermost one of the third channel layers distal from the substrate is level with an upper surface of an uppermost one of the one or more second channel layers, and wherein a lower surface of a lowermost one of the third channel layers closest to the substrate is level with a lower surface of a lowermost one of the one or more first channel layers.

2. The semiconductor device of claim 1, wherein the one or more first channel layers comprise a plurality of first channel layers having a uniform spacing therebetween, the one or more second channel layers comprise a plurality of second channel layers having a uniform spacing therebetween, and the third channel layers have a non-uniform spacing therebetween.

3. The semiconductor device of claim 1, wherein the third channel layers comprise:
one or more lower channel layers;
a first intermediate channel layer over the one or more lower channel layers;
a second intermediate channel layer over the first intermediate channel layer; and
one or more upper channel layers over the second intermediate channel layer, wherein each of the first intermediate channel layer and the second intermediate channel layer has a thickness different from a first thickness of the one or more lower channel layers and a second thickness of the one or more upper channel layers.

4. The semiconductor device of claim 3, wherein the first thickness of the one or more lower channel layers is the same as the second thickness of the one or more upper channel layers, wherein the first intermediate channel layer and the second intermediate channel layer have different thicknesses.

5. The semiconductor device of claim 3, wherein the third gate structure comprises:
a first portion disposed between the first intermediate channel layer and the second intermediate channel layer; and
a second portion disposed between the second intermediate channel layer and an adjacent one of the one or more upper channel layers, wherein a width of the first portion is smaller than a width of the second portion.

6. The semiconductor device of claim 5, wherein the third channel layers have a same width.

7. The semiconductor device of claim 3, wherein the NSFET device further comprises a third source/drain region connected to the third channel layers, wherein the third source/drain region extends continuously from a lowermost one of the third channel layers closest to the substrate to an uppermost one of the third channel layers distal from the substrate.

8. The semiconductor device of claim 7, wherein the CFET device further comprises:
a first source/drain region connected to the one or more first channel layers, the first source/drain region extending from the first fin to the isolation structure; and
a second source/drain region connected to the one or more second channel layers, the second source/drain region extending from the isolation structure to an uppermost one of the one or more second channel layers, wherein the second source/drain region is disposed above the first source/drain region and is separated from the first source/drain region by the isolation structure.

9. The semiconductor device of claim 7, wherein the NSFET device further comprises a first inner spacer disposed between the first intermediate channel layer and the second intermediate channel layer, wherein a first sidewall of the first inner spacer facing the third gate structure is a curved sidewall.

10. The semiconductor device of claim 9, wherein a second sidewall of the first inner spacer facing away from the third gate structure is another curved sidewall, wherein the second sidewall of the first inner spacer is recessed from a first sidewall of the first intermediate channel layer, wherein the first sidewall of the first intermediate channel layer and the second sidewall of the first inner spacer are in contact with the third source/drain region.

11. The semiconductor device of claim 10, wherein the NSFET device further comprises a second inner spacer disposed between the first intermediate channel layer and an adjacent one of the one or more lower channel layers, wherein a sidewall of the second inner spacer facing away from the third gate structure is flush with the first sidewall of the first intermediate channel layer.

12. A semiconductor device comprising:
a substrate;
a complementary field-effect transistor (CFET) device over a first region of the substrate, the CFET device comprising:
a first fin over the substrate;
one or more first channel layers stacked vertically over the first fin;
a first gate structure around the one or more first channel layers;
one or more second channel layers stacked vertically over the one or more first channel layers;
a second gate structure around the one or more second channel layers; and
an isolation structure between the one or more first channel layers and the one or more second channel layers; and
a nanostructure field-effect transistor (NSFET) device over a second region of the substrate, the NSFET device comprising:
a second fin over the substrate;
third channel layers stacked vertically over the second fin, wherein the third channel layers have a non-uniform spacing, wherein the third channel layers comprise:
one or more lower channel layers;
one or more upper channel layers over the one or more lower channel layers; and
a first intermediate channel layer and a second intermediate channel layer between the one or more lower channel layers and the one or more upper channel layers, wherein each of the first intermediate channel layer and the second intermediate channel layer has a thickness different from a thickness of the one or more lower channel layers and a thickness of the one or more upper channel layers; and
a third gate structure around the third channel layers.

13. The semiconductor device of claim 12, wherein the third gate structure comprises:
a first portion disposed between the first intermediate channel layer and the second intermediate channel layer; and
a second portion disposed between the first intermediate channel layer and an adjacent one of the one or more lower channel layers, wherein a width of the first portion is smaller than a width of the second portion.

14. The semiconductor device of claim 12, wherein the one or more lower channel layers and the one or more upper channel layers have a same thickness.

15. The semiconductor device of claim 12, wherein an upper surface of an uppermost one of the third channel layers distal from the substrate is level with an upper surface of an uppermost one of the one or more second channel layers, and wherein a lower surface of a lowermost one of the third channel layers closest to the substrate is level with a lower surface of a lowermost one of the one or more first channel layers.

16. The semiconductor device of claim 12, wherein the CFET device further comprises:
first source/drain regions on opposing sides of the one or more first channel layers, the first source/drain regions extending from the first fin to the isolation structure; and
second source/drain regions on opposing sides of the one or more second channel layers, the second source/drain regions extending from the isolation structure to an uppermost one of the one or more second channel layers,
wherein the NSFET device further comprises third source/drain regions on opposing sides of the third channel layers, wherein the third source/drain regions extend continuously from a lowermost one of the third channel layers closest to the substrate to an uppermost one of the third channel layers distal from the substrate.

17. A method of forming a semiconductor device, the method comprising:
forming a multi-layer stack over a substrate, the multi-layer stack extending over a first device region of the substrate and a second device region of the substrate, the multi-layer stack comprising:
a lower multi-layer stack comprising one or more layers of a semiconductor material interleaved with one or more layers of a first dummy material;
a layer of a second dummy material over the lower multi-layer stack; and
an upper multi-layer stack over the layer of the second dummy material, the upper multi-layer stack comprising one or more layers of the semiconductor material interleaved with one or more layers of the first dummy material;
patterning the substrate and multi-layer stack to form a first fin and a first nanostructure over the first fin in the first device region, and a second fin and a second nanostructure over the second fin in the second device region, wherein each of the first nanostructure and the second nanostructure comprises:
a lower nanostructure comprising corresponding layers of materials in the lower multi-layer stack;
an upper nanostructure over the lower nanostructure and comprising corresponding layers of materials in the upper multi-layer stack; and
a sacrificial layer comprising the second dummy material and interposed between the lower nanostructure and the upper nanostructure;
forming a first dummy gate structure and a second dummy gate structure over the first nanostructure and the second nanostructure, respectively;
forming a mask layer, wherein the mask layer covers the first nanostructure in the first device region and exposes the second nanostructure in the second device region;
after forming the mask layer, selectively removing the sacrificial layer disposed under the second dummy gate structure to form a gap between the lower nanostructure of the second nanostructure and the upper nanostructure of the second nanostructure;
partially filling the gap by forming the semiconductor material in the gap along an upper surface of the lower nanostructure of the second nanostructure facing the gap to form a first intermediate semiconductor layer, and along a lower surface of the upper nanostructure of the second nanostructure facing the gap to form a second intermediate semiconductor layer;
after the partially filling, filling a remaining portion of the gap between the first intermediate semiconductor layer and the second intermediate semiconductor layer with the first dummy material;
removing the mask layer; and
after removing the mask layer, replacing the sacrificial layer of the first nanostructure with an isolation structure.

18. The method of claim 17, wherein the first dummy gate structure overlies a first portion of the first nanostructure, wherein the first portion of the first nanostructure comprises a first portion of the upper nanostructure and a first portion of the lower nanostructure, and wherein the method further comprises, after replacing the sacrificial layer of the first nanostructure with the isolation structure:
removing the first dummy gate structure to expose the first portion of the first nanostructure;
selectively removing the first dummy material of the first portion of the first nanostructure, wherein after selectively removing the first dummy material of the first portion of the first nanostructure, the semiconductor material of the first portion of the lower nanostructure and the semiconductor material of the first portion of the upper nanostructure remain and form lower channel layers and upper channel layers, respectively; and
forming a lower gate structure around the lower channel layers and forming an upper gate structure around the upper channel layers.

19. The method of claim 18, wherein the second dummy gate structure overlies a second portion of the second nanostructure, wherein the method further comprises, after replacing the sacrificial layer:
removing the second dummy gate structure to expose the second portion of the second nanostructure;
selectively removing the first dummy material of the second portion of the second nanostructure and the first dummy material filling the remaining portion of the gap, wherein after selectively removing the first dummy material of the second portion of the second nanostructure and the first dummy material filling the remaining portion of the gap, the semiconductor material of the second portion of the second nanostructure, the first intermediate semiconductor layer, and the second intermediate semiconductor layer remain and form third channel layers; and
forming a third gate structure around the third channel layers, wherein a portion of the third gate structure formed between the first intermediate semiconductor layer and the second intermediate semiconductor layer has a width smaller than a width of another portion of the third gate structure.

20. The method of claim 17, wherein the one or more layers of the semiconductor material in the lower multi-layer stack and the one or more layers of the semiconductor material in the upper multi-layer stack are formed to have a first thickness, wherein the first intermediate semiconductor layer is formed to have a second thickness, and the second intermediate semiconductor layer is formed to have a third thickness, wherein the second thickness and the third thickness are different from the first thickness.
